(19) United States
(12) Patent Application Publication
(10) Pub. No.: US 2026/0305082 A1
(43) Pub. Date: Oct. 1, 2026

(54) DISPLAY DEVICE

(71) Applicant: LG DISPLAY CO., LTD., Seoul (KR)

(72) Inventors: Min Ki KIM, Paju-si (KR); Ki Soub YANG, Paju-si (KR); Sung Goo JUNG, Paju-si (KR); Hak Min LEE, Paju-si (KR)

(73) Assignee: LG DISPLAY CO., LTD., Seoul (KR)

(21) Appl. No.: 19/571,000

(22) Filed: Mar. 18, 2026

(30) Foreign Application Priority Data
Mar. 31, 2025 (KR) 10-2025-0041113

(51) Int. Cl. H10K 59/122; H10K 59/35

(52) U.S. Cl. CPC H10K 59/122; H10K 59/353

(57) ABSTRACT

A display device may include: first, second, and third sub-pixels having different colors, each being partitioned into at least two sub-pixel regions by a trench; a pixel including one of first sub-pixel regions partitioned in the first sub-pixel, one of second sub-pixel regions partitioned in the second sub-pixel, and one of third sub-pixel regions partitioned in the third sub-pixel; transistors each corresponding to a respective one of the first, second, and third sub-pixel region; an insulating layer on the transistors; a plurality of first electrodes on the insulating layer, each corresponding to a respective one of the first, second, and third sub-pixel regions, and connected to a corresponding transistor; an organic electroluminescent compound layer disposed on the plurality of first electrodes; and a second electrode disposed on an upper portion of the organic electroluminescent compound layer. The trench is provided within the insulating layer.

### CROSS-REFERENCE TO RELATED APPLICATIONS

This application claims the benefit of and priority to Korean Patent Application No. 10-2025-0041113, filed Mar. 31, 2025, the entire contents of which are incorporated herein by reference for all purposes.

### BACKGROUND

### 1. Technical Field

The present disclosure relates to a display device. More specifically, for example, without limitation, the present disclosure relates to a display device for displaying images.

### 2. Description of Related Art

With the development of the information society, the demand for display devices for displaying images has increased in various forms. Accordingly, various display devices such as liquid crystal display (LCD) devices, plasma display panel (PDP) devices, quantum-dot light emitting display (QLED) devices, and organic light-emitting display (OLED) devices have been used in recent years.

Recently, head-mounted displays (HMDs) including such display devices have been developed. The head-mounted display is a glasses-type monitor device of virtual reality (VR) or augmented reality (AR) that is worn in the form of glasses or a helmet to form a focus at a close distance in front of the user's eyes. For such a head-mounted display, reducing a distance between pixels and increasing a light-emitting area are important to improve performance. However, the reduced distance may cause leakage current between pixels and brings challenges in manufacturing.

The description of related art should not be considered prior art merely because it is mentioned in or associated with this section. The description of related art includes information that describes one or more aspects of the subject technology, and the description in this section does not limit the scope of the present disclosure.

### SUMMARY

One or more aspects of the present disclosure are directed to providing a display device capable of improving a degree of fabrication freedom of a fine metal mask (FMM) by ensuring that an anode area of a light-emitting element matches an emission area of an emission material layer (EML) in a ratio greater than or equal to 1:2 to overcome the manufacturing technology and mass productivity limits of the FMM, which are necessary for implementing an ultra-high-resolution display.

The objectives of the present disclosure are not limited to the objectives mentioned above, and other objectives not mentioned will be clearly understood by those skilled in the art from the description below.

A display device according to an embodiment of the present disclosure may include: first, second, and third sub-pixels defined on a substrate and having different colors, each being partitioned into at least two sub-pixel regions by a trench; a pixel including at least one of first sub-pixel regions partitioned in the first sub-pixel, at least one of second sub-pixel regions partitioned in the second sub-pixel, and at least one of third sub-pixel regions partitioned in the third sub-pixel; a plurality of thin film transistors, wherein each thin film transistor is disposed to correspond to a respective one of a first sub-pixel region, a second sub-pixel region, and a third sub-pixel region; an insulating layer provided on the plurality of thin film transistors; a plurality of first electrodes disposed on the insulating layer, wherein each first electrode corresponds to a respective one of the first, second, and third sub-pixel regions, and each first electrode is connected to a corresponding one of the plurality of thin film transistors; an organic electroluminescent compound layer disposed on the plurality of first electrodes; and a second electrode disposed on an upper portion of the organic electroluminescent compound layer, wherein the trench is provided within the insulating layer, and wherein the first sub-pixel region comprises the at least one of the first sub-pixel regions, the second sub-pixel region comprises the at least one of the second sub-pixel regions, and the third sub-pixel region comprises the at least one of the third sub-pixel regions.

A display device according to another embodiment of the present disclosure may include: first, second, and third sub-pixels defined on a substrate and having different colors, each being partitioned into at least four sub-pixel regions by a trench; and a pixel including at least one of first sub-pixel regions partitioned in the first sub-pixel, at least one of second sub-pixel regions partitioned in the second sub-pixel, and at least one of third sub-pixel regions partitioned in the third sub-pixel; wherein a plurality of pixels form a group and are repeatedly disposed covering the substrate.

According to one or more aspects of the present disclosure, a degree of fabrication freedom of an FMM can be improved by ensuring that an anode area of a light-emitting element matches an emission area of an EML in a ratio greater than or equal to 1:2 to overcome the manufacturing technology and mass productivity limits of the FMM, which are necessary for implementing an ultra-high-resolution display.

According to one or more aspects of the present disclosure, the difficulty of a mask fabrication process can be reduced by increasing an opening area of an FMM by at least two times, and mass productivity can be improved by reducing mask clogging problems through the increased opening area.

According to one or more aspects of the present disclosure, self-pixelization is achievable with one sub-pixel size by using a trench, even when the area of an emission material layer is four times larger.

The effects of the present disclosure are not limited to the effects mentioned above, and other effects not mentioned may be clearly understood by those skilled in the art from the description of the claims.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view illustrating a display device according to an embodiment of the present disclosure;

FIG. 2 is a plan view schematically illustrating a first substrate;

FIG. 3 is a plan view schematically illustrating a trench of sub-pixels;

FIG. 4 is a plan view illustrating pixels composed of red, green, and blue sub-pixel regions in the display device according to an embodiment of the present disclosure;

FIG. 5 is a cross-sectional view taken along line I-I′ of FIG. 4;

FIG. 6 is a cross-sectional view schematically illustrating an example of the configuration for first electrodes, light-emitting layers, and a second electrode of four sub-pixel regions disposed in a green sub-pixel in the display device according to an embodiment of the present disclosure;

FIG. 7 is a cross-sectional view taken along line II-II′ of FIG. 4 as a first embodiment of the present disclosure;

FIG. 8 is an enlarged cross-sectional view of a part A of FIG. 7;

FIG. 9 is a cross-sectional view schematically illustrating an example of the configuration for first electrodes, light-emitting layers, and a second electrode of two green, red, and blue sub-pixel regions within green, blue, and red sub-pixels, in the display device according to the first embodiment of the present disclosure;

FIGS. 10A and 10B are process cross-sectional views illustrating a manufacturing method of the display device according to the first embodiment of the present disclosure;

FIG. 11 is a plan view illustrating a case where a first mask for forming a green EML is applied to form a green EML G-EML in green sub-pixel regions in the display device according to the first embodiment of the present disclosure;

FIG. 12 is a plan view illustrating a case where a second mask for forming a red EML is applied to form a red EML R-EML in red sub-pixel regions in the display device according to the first embodiment of the present disclosure;

FIG. 13 is a plan view illustrating a case where a third mask for forming a blue EML is applied to form a blue EML B-EML in blue sub-pixel regions in the display device according to the first embodiment of the present disclosure;

FIG. 14 is a cross-sectional view taken along line II-II′ of FIG. 4, as a second embodiment of the present disclosure;

FIG. 15 is a cross-sectional view schematically illustrating an example of the configuration for first electrodes, light-emitting layers, and a second electrode of each of two green, red, and blue sub-pixel regions among green, red, and blue sub-pixel regions in the display device according to the second embodiment of the present disclosure;

FIG. 16 is a plan view illustrating a pixel composed of red, green, and blue sub-pixel regions of a display device according to a third embodiment of the present disclosure;

FIG. 17 is a plan view illustrating a pixel composed of red, green, and blue sub-pixel regions of a display device according to a fourth embodiment of the present disclosure;

FIG. 18 is a plan view illustrating a pixel composed of red, green, and blue sub-pixel regions of a display device according to a fifth embodiment of the present disclosure; and

FIG. 19 is a plan view illustrating a pixel composed of red, green, and blue sub-pixel regions of a display device according to a sixth embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure and a method of achieving the same should become clear with embodiments described in detail below with reference to the accompanying drawings. However, the present disclosure is not limited to the embodiments disclosed below and may be implemented with a variety of different forms. The present embodiments are merely provided to allow those skilled in the art to completely understand the scope of the present disclosure, and the present disclosure is defined only by the scope of the claims.

The figures, dimensions, ratios, angles, numbers, and the like disclosed in the drawings for describing the embodiments of the present disclosure are merely illustrative and are not limited to matters shown in the present disclosure. Further, in describing the present disclosure, detailed descriptions of well-known technologies will be omitted when it is determined that they may unnecessarily obscure the gist of the present disclosure.

Terms such as “comprising,” “constituting,” “including,” “having,” and “composed of” used herein are intended to allow other elements to be added unless the terms are used with the term “only.” When a component is expressed in the singular form, it may include a case in which the plural form is included unless otherwise explicitly stated. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted as including an ordinary error range even when not expressly stated.

For the description of a positional relationship, for example, when the positional relationship between two parts is described as “on,” “above,” “below,” “next to,” and the like, one or more parts may be interposed therebetween unless the term “immediately” or “directly” is used in the expression.

When an element or layer is disposed “on” another element or layer, the element is disposed directly on another element or layer or disposed on another element another layer with still another element therebetween.

In addition, the terms “first,” “second,” and the like may be used herein to describe various components, the components are not limited by the terms. These terms are used only to distinguish one component from another. Accordingly, a first component discussed below could be termed a second component without departing from the teachings of the present disclosure.

Like reference numerals generally denote like elements throughout the specification.

The size and thickness of each component illustrated in the drawings are shown for convenience of description, and the present disclosure is not necessarily limited to the size and thickness of the component illustrated.

The features of various embodiments of the present disclosure may be partially or entirely bonded to or combined with each other. The embodiments may be interoperated and performed in various ways technically and may be carried out independently of or in association with each other.

Hereinafter, an example of a display device according to one or more aspects of the present disclosure will be described in detail with reference to the accompanying drawings. In adding reference numerals to components in each drawing, the same components may have the same reference numerals as much as possible even though they are indicated on different drawings.

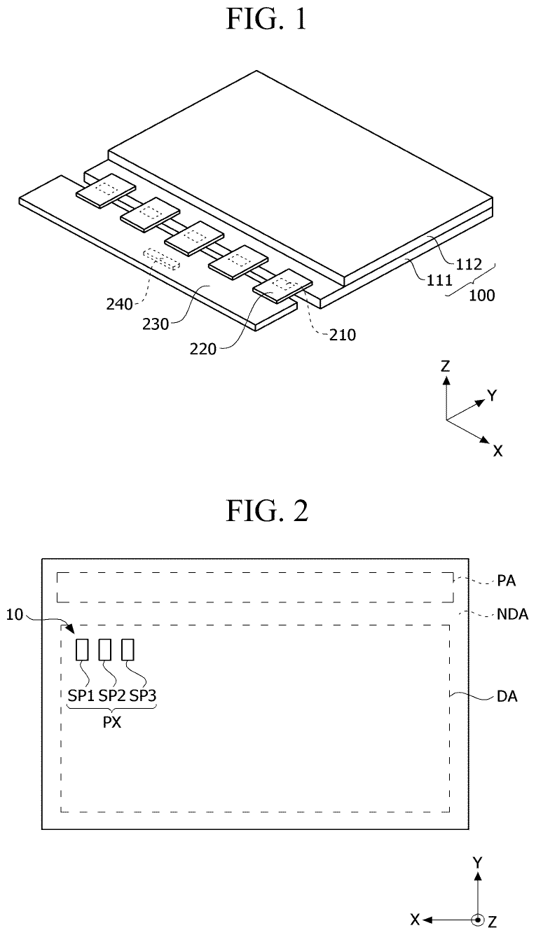

FIG. 1 is a perspective view illustrating a display device according to an embodiment of the present disclosure.

Referring to FIG. 1, the display device according to one embodiment of the present disclosure includes a display panel 100, source driver integrated circuits (hereinafter referred to as “source driver ICs”) 210, flexible films 220, and a circuit board 230, and a timing controller 240.

The display panel 100 includes a first substrate 111 and a second substrate 112. The second substrate 112 may be an encapsulation substrate. Gate lines, data lines, and pixels may be formed on one surface of the first substrate 111 facing the second substrate 112.

The pixels may be provided in an area defined by an intersection structure of the gate lines and the data lines. Each of the pixels may include a light-emitting element that includes a thin-film transistor, a first electrode, an emission material layer, and a second electrode. Each of the pixels may be provided in the area defined by an intersection structure of the gate lines and the data lines using the thin-film transistor.

Each of the pixels may include a light-emitting element that includes a thin-film transistor, a first electrode, an emission material layer, and a second electrode. Each of the pixels supplies a predetermined current to an organic light-emitting element according to a data voltage of the data line when a gate signal from the gate line is input thereto using a thin-film transistor. Accordingly, the organic light-emitting element of each of the pixels may emit light with a predetermined brightness according to the predetermined current. The display panel 100 may be divided into a display area in which pixels are formed to display an image, and a non-display area in which an image is not displayed. The gate lines, the data lines, and the pixels may be formed in the display area. A gate driver and pads may be formed in the non-display area.

The gate driver supplies gate signals to the gate lines according to a gate control signal input from the timing controller 240. The gate driver may be formed in the non-display area outside one side or both sides of the display area of the display panel 100 by a gate driver-in-panel (GIP) method. Alternatively, the gate driver may be fabricated as a driving chip, may be mounted on a flexible film, and may be attached to the non-display area outside one side or both sides of the display area of the display panel 100 by a tape automated bonding (TAB) method.

The source driver IC 210 receives digital video data and a source control signal from the timing controller 240. The source driver IC 210 converts the digital video data into analog data voltages according to the source control signal, and supplies the analog data voltages to the data lines. When the source driver IC 210 is fabricated as a driving chip, the source driver IC 210 may be mounted on the flexible film 220 by a chip-on-film (COF) method or a chip-on-plastic (COP) method.

The pads, such as data pads, may be formed in the non-display area of the display panel 100. Lines connecting the pads to the source driver IC 210 and lines connecting the pads to lines of the circuit board 230 may be formed in the flexible film 220. The flexible film 220 may be attached onto the pads using an anisotropic conducting film, so that the pads may be connected to the lines of the flexible film 220.

The circuit board 230 may be attached onto the flexible films 220. A plurality of circuits implemented as driving chips may be mounted on the circuit board 230. For example, the timing controller 240 may be mounted on the circuit board 230. The circuit board 230 may be a printed circuit board or a flexible printed circuit board.

The timing controller 240 receives digital video data and a timing signal from an external system board through a cable of the circuit board 230. The timing controller 240 generates a gate control signal for controlling an operation timing of the gate driver and a source control signal for controlling the source driver ICs 210 based on the timing signal. The timing controller 240 supplies the gate control signal to the gate driver, and supplies the source control signal to the source driver ICs 210.

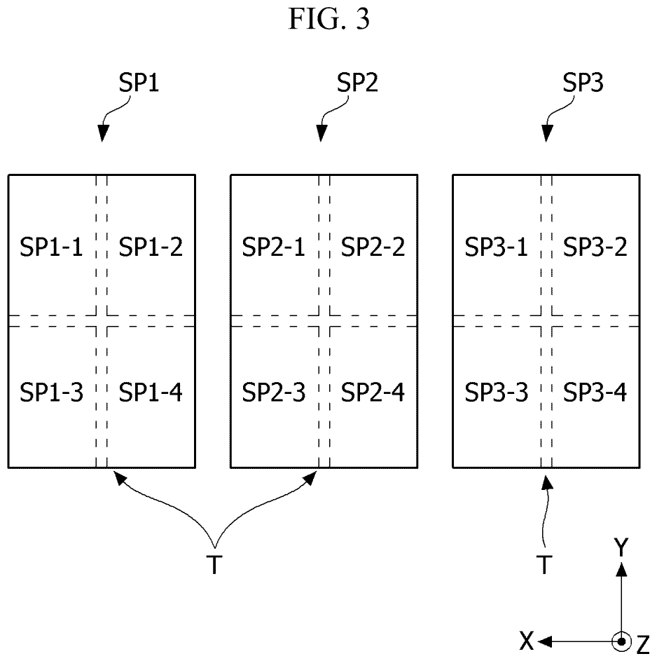

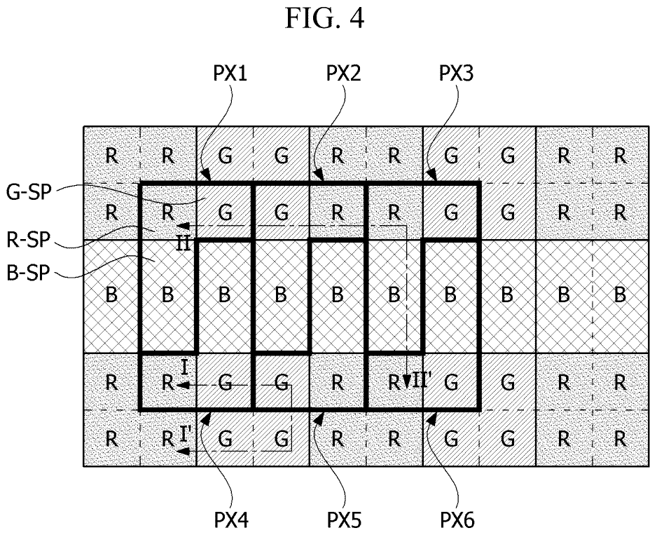

FIG. 2 is a plan view schematically illustrating a first substrate, FIG. 3 is a plan view schematically illustrating a trench of sub-pixels, and FIG. 4 is a plan view illustrating pixels composed of red, green, and blue sub-pixel regions in the display device according to an embodiment of the present disclosure.

Referring to FIGS. 2 and 3, the first substrate 111 is defined into a display area DA and a non-display area NDA, and the non-display area NDA may include a pad area PA in which pads are formed.

In the display area DA, data lines and gate lines intersecting the data lines may be formed. In addition, in the display area DA, sub-pixels 10 for displaying an image in a matrix form may be formed at intersection areas of the data lines and the gate lines.

Each of pixels PX may include a first sub-pixel SP1, a second sub-pixel SP2, and a third sub-pixel SP3. The first sub-pixel SP1 may be provided to discharge green light, the second sub-pixel SP2 may be provided to discharge red light, and the third sub-pixel SP3 may be provided to discharge blue light. However, embodiments of the present disclosure are not necessarily limited thereto. Each of pixels PX may further include a fourth sub-pixel which discharges white light. In addition, the arrangement order of the first, second and third sub-pixels SP1, SP2, and SP3 constituting each of the pixels PX may be variously changed.

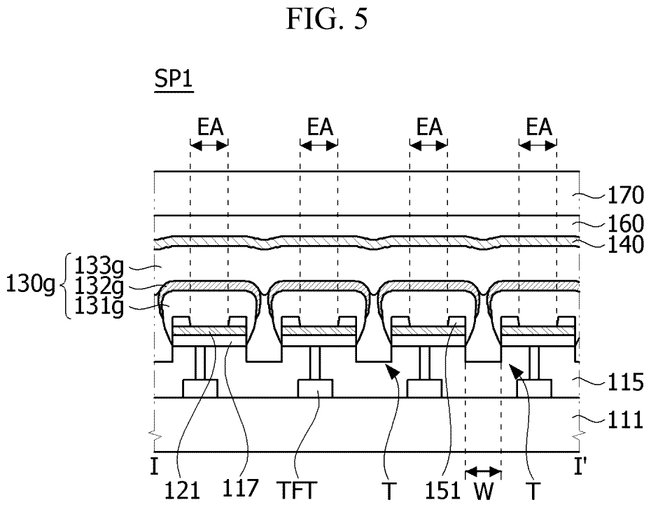

Referring to FIG. 3, a first sub-pixel SP1 of green may include four first sub-pixel regions of green defined by a trench T (also shown in FIG. 5). The first sub-pixel regions may be partitioned into first-first to first-fourth sub-pixel regions SP1-1, SP1-2, SP1-3, and SP1-4.

In this case, the green first-first to first-fourth sub-pixel regions SP1-1, SP1-2, SP1-3, and SP1-4 in FIG. 3 may include one green sub-pixel region G-SP or G constituting a first pixel PX1, one green sub-pixel region G-SP or G constituting a second pixel PX2, and two green sub-pixel regions G-SP or G adjacent to the upper portion of those two green sub-pixel regions G-SP or G constituting the first and second pixels PX1, PX2, as in FIG. 4, and the green first-first to first-fourth sub-pixel regions SP1-1, SP1-2, SP1-3, and SP1-4 may be identically defined as four green sub-pixel regions. However, the present disclosure is not limited thereto.

In addition, referring to FIG. 3, a red second sub-pixel SP2 may include four red second sub-pixel regions defined by a trench T (also shown in FIG. 5). The second sub-pixel regions may be partitioned into second-first to second-fourth sub-pixel regions SP2-1, SP2-2, SP2-3, and SP2-4.

In this case, the second-first to second-fourth red sub-pixel regions SP2-1, SP2-2, SP2-3, and SP2-4 in FIG. 3 may include one red sub-pixel region R-SP or R constituting the second pixel PX2, one red sub-pixel region R-SP or R constituting the third pixel PX3, and two red sub-pixel regions R-SP or R adjacent to the upper portion of those two red sub-pixel regions R-SP or R constituting the second and third pixels PX2, PX3, as in FIG. 4 and the second-first to second-fourth red sub-pixel regions SP2-1, SP2-2, SP2-3, and SP2-4 may be identically defined as four red sub-pixel regions. However, the present disclosure is not limited thereto.

In addition, referring to FIG. 3, a blue third sub-pixel SP3 may include four blue third sub-pixel regions defined by a trench T (also shown in FIG. 5). The third sub-pixel regions may be partitioned into third-first to third-fourth sub-pixel regions SP3-1, SP3-2, SP3-3, and SP3-4. In this case, the blue third-first to third-fourth sub-pixel regions SP3-1, SP3-2, SP3-3, and SP3-4 in FIG. 3 may be identically defined as two blue sub-pixel regions B-SP or B including one blue sub-pixel region B-SP or B (consisting of the third-second and third-fourth sub-pixel regions SP3-2, SP3-4) constituting the second pixel PX2 and one blue sub-pixel region B-SP or B (consisting of the third-first and third-third sub-pixel regions SP3-1, SP3-3) constituting the fourth pixel PX4, as in FIG. 4. However, the present disclosure is not limited thereto. A trench in a vertical or horizontal direction may be formed in the blue third sub-pixel SP3, and the blue third sub-pixel SP3 may include two blue third sub-pixel regions defined by the trench, but the present disclosure is not necessarily limited thereto.

In the embodiments of the present disclosure, each of the first, second and third sub-pixels SP1, SP2, and SP3 is described as having four sub-pixel regions, but it is not necessarily limited thereto. For example, the embodiments of the present disclosure describe a case where each of the first, second and third sub-pixels SP1, SP2, and SP3 is partitioned into four green sub-pixel regions G-SP or G, four red sub-pixel regions R-SP or R, or four blue sub-pixel regions B-SP or B. However, each of the first, second and third sub-pixel SP1, SP2, or SP3 may be defined by being partitioned into at least two sub-pixel regions, for example, two or more green sub-pixel regions G-SP or G, two or more red sub-pixel regions R-SP or R, or two or more blue sub-pixel regions B-SP or B.

Referring to FIG. 4, each of the plurality of first to sixth pixels PX1 to PX6 may be composed of a combination of at least one green sub-pixel region G, at least one red sub-pixel region R, and at least one blue sub-pixel region B having different colors.

Referring to FIG. 4, the first to sixth pixels PX1 to PX6, the number of which is six, form one group and may be repeatedly disposed covering (or disposed on) the entire surface of the first substrate 111 in a matrix direction. For example, each of the first to sixth pixels PX1 to PX6 may be implemented by a combination of red, green, and blue sub-pixel regions R-SP, G-SP, and B-SP. In this case, the red, green, and blue sub-pixel regions R-SP, G-SP, and B-SP may be collectively referred to as red, green, and blue sub-pixel regions R, G, and B for convenience.

In addition, the blue sub-pixel region B of each of the first to sixth pixels PX1 to PX6 has a larger area than those of the red sub-pixel region R and the green sub-pixel region G. This is because the brightness of the blue sub-pixel region B is lower than those of the red sub-pixel region R and the green sub-pixel region G, and thus the area of the blue sub-pixel region B may be formed to be larger than those of the red and green sub-pixel regions R and G to compensate for the brightness.

According to one or more aspects of the present disclosure, in order to overcome the manufacturing technology and mass-producibility limits of a fine metal mask (FMM) required for implementing the red, green and blue sub-pixel regions R, G, and B in an ultra-high resolution display, an anode area of a light-emitting element and an EML light-emitting area, i.e., an area requiring the fine metal mask (FMM), may be formed in a ratio of at least 1:2, rather than the conventional 1:1 matching. For example, the degree of freedom in manufacturing the FMM may be improved by four times by matching the anode area and the EML light-emitting area in a ratio of 1:4.

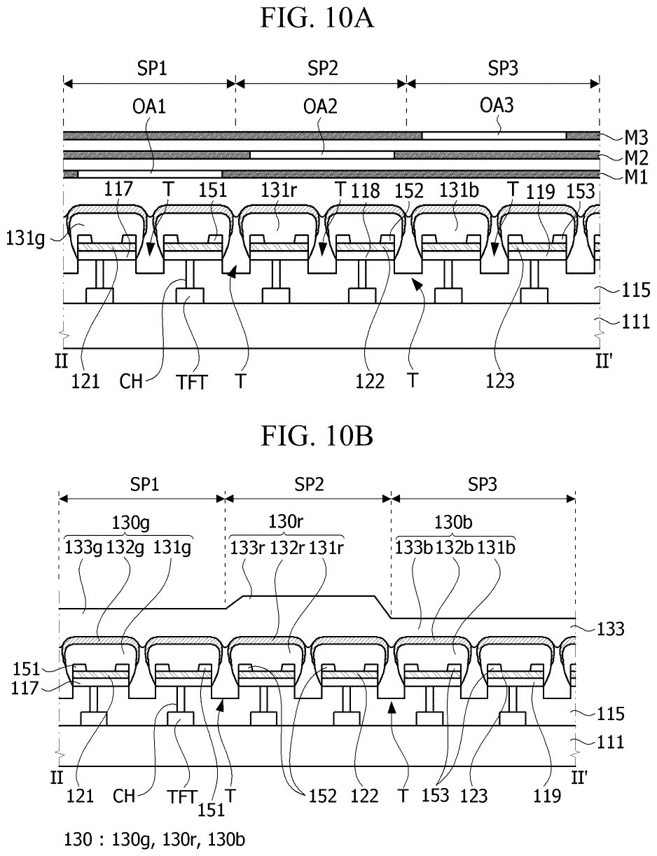

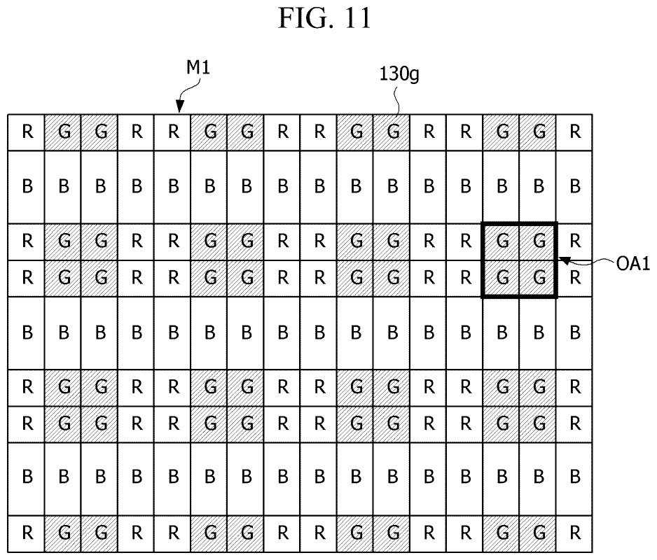

In particular, each of the green first sub-pixel SP1, the red second sub-pixel SP2, and the blue third sub-pixel SP3 may be partitioned into at least two sub-pixel regions. For example, each of the first to third sub-pixels SP1 to SP3 may be partitioned into four green sub-pixel regions G, red sub-pixel regions R, and blue sub-pixel regions B, and by using first, second, and third fine metal masks (FMMs) (M1, M2, and M3 of FIG. 10A), the light-emitting area of the EML constituting the light-emitting layers of each sub-pixel may be improved fourfold. Accordingly, the difficulty of the mask manufacturing process may be lowered. In addition, since a mask clogging problem may be reduced as the opening areas (OA1, OA2, and OA3 in FIG. 10A) of the fine metal masks (M1, M2, and M3 in FIG. 10A) are widened compared to the conventional ones, mass-producibility may be secured.

Each of the green, red, and blue sub-pixel regions G, R, and B supplies a predetermined current to a light-emitting element according to a data voltage of the data line when a gate signal of the gate line is input.

As a result, the light-emitting element of each of the green, red, and blue sub-pixel regions G, R, and B may emit light with a predetermined brightness according to a predetermined current. In addition, a power supply voltage is supplied to a power line. The power line supplies the power supply voltage to each of the green, red, and blue sub-pixel regions G, R, and B.

Hereinafter, the structures of the green, red, and blue sub-pixel regions G, R, and B according to the first embodiment of the present disclosure will be described in more detail.

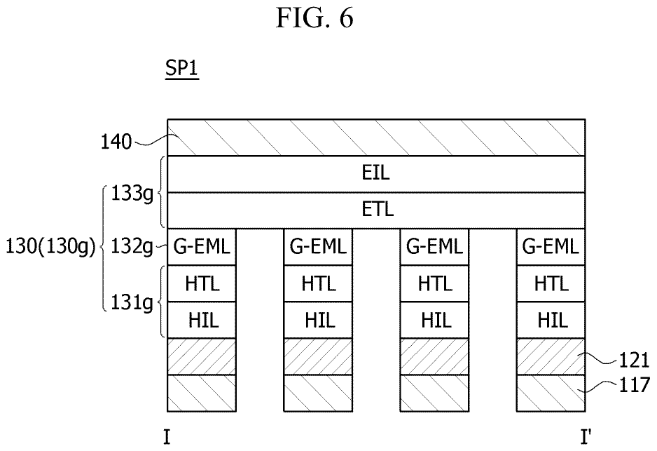

FIG. 5 is a cross-sectional view taken along line I-I′ of FIG. 4, and FIG. 6 is a cross-sectional view schematically illustrating an example of the configuration for first electrodes, light-emitting layers, and a second electrode of four green sub-pixel regions disposed in a green sub-pixel, in the display device according to an embodiment of the present disclosure. For example, FIG. 6 may be a view illustrating the arrangement relationship of the first electrodes, light-emitting layers, and second electrode of the four green sub-pixel regions based on line I-I′.

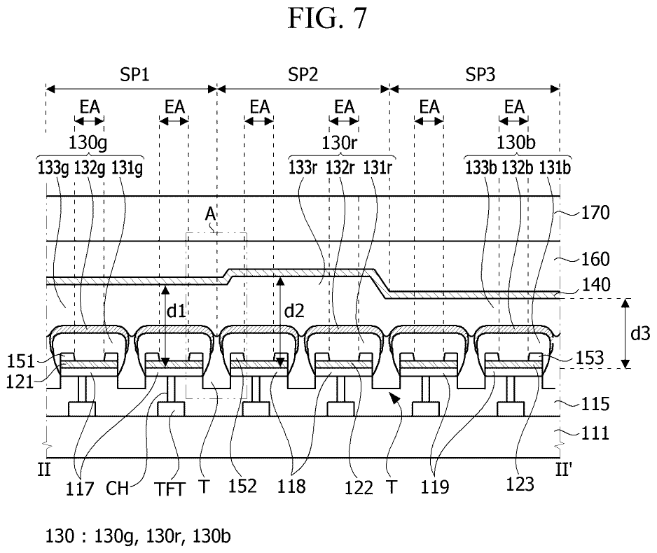

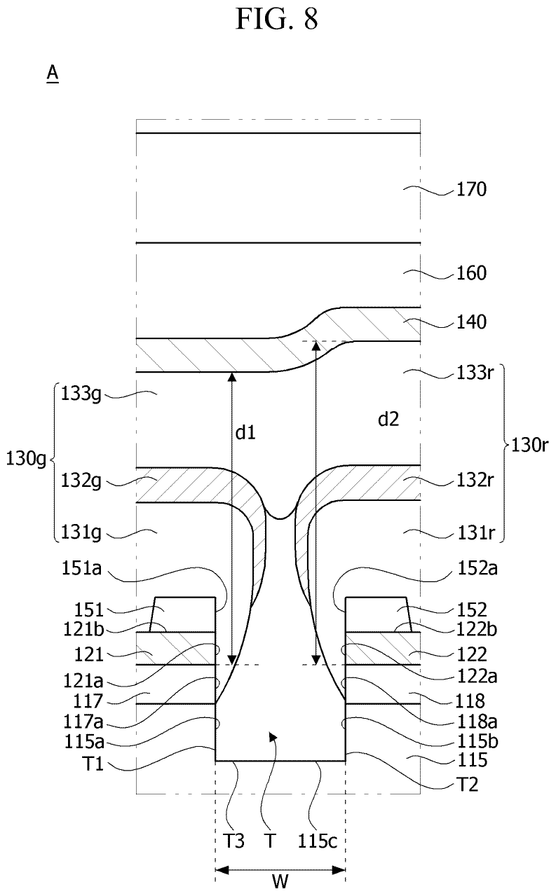

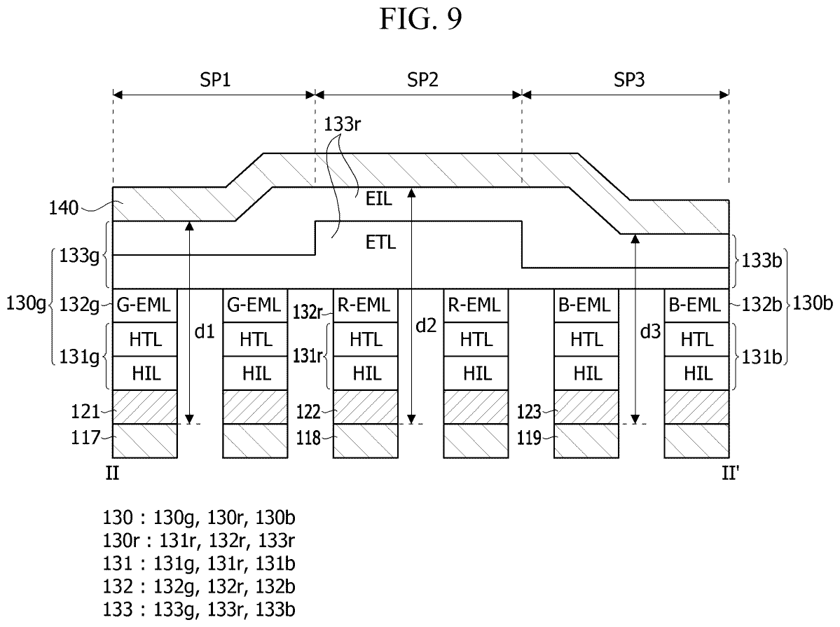

In addition, FIG. 7 is a cross-sectional view taken along line II-II′ of FIG. 4, FIG. 8 is an enlarged cross-sectional view of a part A of FIG. 7, and FIG. 9 is a cross-sectional view schematically illustrating an example of the configuration for first electrodes, light-emitting layers, and a second electrode of each of two green, red, and blue sub-pixel regions among four green, red, and blue sub-pixel regions in green, blue, and red sub-pixels in the display device according to the first embodiment of the present disclosure. For example, FIG. 9 may be a view illustrating the arrangement relationship of the first electrodes, light-emitting layers, and second electrode of the two green, red, and blue sub-pixel regions based on line II-II′.

The first substrate 111 may be defined into a display area DA and a non-display area NDA. A pad area PA in which pads are disposed may be formed in the non-display area NDA.

In the display area DA, data lines and gate lines intersecting the data lines may be formed. In addition, in the display area DA, sub-pixels 10 for displaying an image in a matrix form may be formed at intersection areas of the data lines and the gate lines.

Further, the sub-pixels 10 may include the first sub-pixel SP1, the second sub-pixel SP2, and a third sub-pixel SP3. The first sub-pixel SP1 may be provided to discharge green light, the second sub-pixel SP2 may be provided to discharge red light, and the third sub-pixel SP3 may be provided to discharge blue light. However, the present disclosure is not necessarily limited thereto. The sub-pixels 10 may further include a fourth sub-pixel which discharges white light. In addition, the arrangement order of the first, second and third sub-pixels SP1, SP2, and SP3 may be variously changed.

Here, when the gate signal of the gate line is input to each of the first, second and third sub-pixels SP1, SP2, and SP3, a predetermined current may be supplied to a light-emitting element according to the data voltage of the data line. Accordingly, the light-emitting element of each of the first, second and third sub-pixels SP1, SP2, and SP3 may emit light with a predetermined brightness according to the predetermined current. In addition, a power supply voltage may be supplied to a power line. The power line may supply the power supply voltage to each of the first, second and third sub-pixels SP1, SP2, and SP3.

The structures of the sub-pixels of the display device according to the first embodiment of the present disclosure will be described in more detail below. Herein, a case where the green sub-pixel (SP1) is partitioned into four sub-pixel regions will be described as an example.

Referring to FIGS. 5 and 7, a driving transistor TFT, an insulating layer 115, first, second, and third reflective electrodes 117, 118, and 119, first-first, first-second and first-third electrodes 121, 122, and 123, an organic electroluminescent compound layer 130, a second electrode 140, an encapsulation film 170, a capping layer 160, first, second, and third banks 151, 152, and 153, and a trench T may be formed on the first substrate 111 facing the second substrate (112 in FIG. 1). The first-first, first-second and first-third electrodes 121, 122 and 123 may be collectively referred to as the first electrodes for convenience.

The first substrate 111 may be made of glass or plastic, but is not necessarily limited thereto, and may be made of a semiconductor material such as a silicon wafer. The first substrate 111 may be made of a transparent material or an opaque material.

The display device according to the first embodiment of the present disclosure may be configured as a top emission type in which emitted light is discharged toward the upper portion, but is not necessarily limited thereto. In a case where the display device according to the first embodiment of the present disclosure is configured as the top emission type in which emitted light is discharged toward the upper portion, the first substrate 111 may be made of an opaque material or a transparent material. Meanwhile, in a case where the display device according to the first embodiment of the present disclosure is configured as a so-called bottom emission type in which emitted light is discharged toward the lower portion, a transparent material may be used for the first substrate 111.

On the first substrate 111, circuit elements including various signal lines, thin film transistors, and capacitors may be formed for each of the sub-pixels (SP1, SP2, and SP3 in FIG. 7). The signal lines may include a gate line, a data line, a power line, and a reference line, and the thin film transistors may include a switching thin film transistor, a driving transistor TFT, and a sensing thin film transistor.

The switching thin film transistor may be switched according to the gate signal supplied to the gate line and serve to supply the data voltage supplied from the data line to the driving transistor TFT.

The driving transistor TFT may be switched according to the data voltage supplied from the switching thin film transistor and serve to generate a data current from power supplied from the power line and supply the data current to the first-first electrode 121.

The sensing thin film transistor serves to sense a threshold voltage deviation of the driving transistor TFT, which causes image quality degradation, and may supply a current of the driving transistor TFT to the reference line in response to a sensing control signal supplied from the gate line or a separate sensing line.

The capacitor serves to maintain the data voltage supplied to the driving transistor TFT for one frame and may be connected to each of a gate terminal and a source terminal of the driving transistor TFT.

The insulating layer 115 may be formed on the circuit elements including the driving transistor TFT. The insulating layer 115 may be formed of an inorganic film, for example, a silicon oxide film (SiOₓ), a silicon nitride film (SiNₓ), or a multilayer thereof, but is not necessarily limited thereto. The insulating layer 115 may also be formed of an organic film, for example, an acrylic resin, an epoxy resin, a phenolic resin, a polyamide resin, a polyimide resin, or the like. The first, second, and third reflective electrodes 117, 118, and 119 and the first-first, first-second and first-third electrodes 121, 122, and 123 may be formed for each of the green first, red second, and blue third sub-pixels SP1, SP2, and SP3 on the insulating layer 115.

The green first sub-pixel SP1 may be partitioned into four green sub-pixel regions (G-SP or G in FIG. 4), and the first reflective electrode 117 and the first-first electrode 121 may be formed in each of the four partitioned green sub-pixel regions (G-SP or G in FIG. 4).

In addition, the red second sub-pixel SP2 may be partitioned into four red sub-pixel regions (R-SP or R in FIG. 4), and the second reflective electrode 118 and the first-second electrode 122 may be formed in each of the four partitioned red sub-pixel regions (R-SP or R in FIG. 4).

Further, the blue third sub-pixel SP3 may be partitioned into four blue sub-pixel regions (B-SP or B in FIG. 4), and the third reflective electrode 119 and the first-third electrode 123 may be formed in each of the four partitioned blue sub-pixel regions (B-SP or B in FIG. 4).

The first, second, and third reflective electrodes 117, 118, and 119 serve as reflectors that reflect light discharged from the organic electroluminescent compound layer 130, and may be formed of alloys of materials including silver (Ag), aluminum (Al), and molybdenum (Mo) having high electrical conductivity and a low work function, or an alloy of silver (Ag) and magnesium (Mg).

The first-first, first-second and first-third electrodes 121, 122, and 123 may be connected to the driving transistor TFT. Specifically, since the first-first, first-second and first-third electrodes 121, 122, and 123 are connected to a source terminal or a drain terminal of the driving transistor TFT through a contact hole CH penetrating the insulating layer 115, a voltage for emitting light may be applied to the first-first, first-second and first-third electrodes 121, 122, and 123.

The first-first, first-second and first-third electrodes 121, 122, and 123 may be made of at least one of a transparent metal material, a transflective metal material, and a metal material having high reflectivity.

In the case where the display device is configured as the top emission type, the first-first, first-second and first-third electrodes 121, 122, and 123 may be made of a metal material having high reflectivity or a stacked structure of a metal material having high reflectivity and a transparent metal material. For example, the first-first, first-second and first-third electrodes 121, 122, and 123 may be formed of a metal material having high reflectivity, such as a stacked structure of aluminum and titanium (Ti/Al/Ti), a stacked structure of aluminum and ITO (ITO/Al/ITO), an Ag alloy, and a stacked structure of an Ag alloy and ITO (ITO/Ag alloy/ITO). The Ag alloy may be an alloy of silver (Ag), palladium (Pd), copper (Cu), and the like.

In the case where the display device is configured as the bottom emission type, the first-first, first-second and first-third electrodes 121, 122, and 123 may be formed of a transparent conductive oxide (TCO) such as an indium tin oxide (ITO) or an indium zinc oxide (IZO) which may transmit light, or a semi-transmissive conductive material such as magnesium (Mg), silver (Ag), or an alloy of magnesium (Mg) and silver (Ag). The first-first, first-second and first-third electrodes 121, 122, and 123 may be anode electrodes.

The first, second, and third banks 151, 152, and 153 may be formed on the first-first, first-second and first-third electrodes 121, 122, and 123 and may define an emission area EA formed in each of the plurality of green first sub-pixels SP1, red second sub-pixels SP2, and blue third sub-pixels SP3, respectively. That is, in a case where the first, second, and third banks 151, 152, and 153 are not formed to cover entire areas of the first-first, first-second and first-third electrodes 121, 122, and 123 in each of the green first sub-pixels SP1, red second sub-pixels SP2, and blue third sub-pixels SP3, the exposed areas of the first-first, first-second and first-third electrodes 121, 122, and 123 may be the emission area EA. In contrast, an area excluding the emission area EA may be a non-emission area.

The first bank 151 may define the emission area EA in each of the green sub-pixel regions (G-SP or G in FIG. 4) partitioned within the green first sub-pixel SP1. In the embodiment of the present disclosure, the first sub-pixel SP1 is described using a green sub-pixel by way of an example, but is not limited thereto.

The second bank 152 may define the emission area EA in each of the red sub-pixel regions (R-SP or R in FIG. 4) partitioned within the red second sub-pixel SP2. In the embodiment of the present disclosure, the second sub-pixel SP2 is described using a red sub-pixel by way of an example, but is not limited thereto.

The third bank 153 may define the emission area EA in each of the blue sub-pixel regions (B-SP or B in FIG. 4) partitioned within the blue third sub-pixel SP3. In the embodiment of the present disclosure, the third sub-pixel SP3 is described using a blue sub-pixel by way of an example, but is not limited thereto.

Since the first, second, and third banks 151, 152, and 153 are formed on the edges of the first-first, first-second and first-third electrodes 121, 122, and 123, it is possible to prevent a decrease in luminous efficiency caused by a current concentration at the ends of the first-first, first-second and first-third electrodes 121, 122, and 123.

Meanwhile, the first, second, and third banks 151, 152, and 153 according to an embodiment of the present disclosure may be formed such that a trench T formed between green, red, and blue sub-pixel regions (G, R, and B in FIG. 4) within the green, red, and blue sub-pixels SP1, SP2, and SP3 is exposed. That is, the first, second, and third banks 151, 152, and 153 may be formed on the upper edges of each of the first-first, first-second and first-third electrodes 121, 122, and 123 formed in each of the green, red, and blue sub-pixel regions (G, R, and B in FIG. 4), but are not limited thereto. For example, the first, second, and third banks 151, 152, and 153 may be formed or may not be formed on side surfaces of each of the first-first, first-second and first-third electrodes 121, 122, and 123.

The first, second, and third banks 151, 152, and 153 may be formed of an inorganic film, for example, a silicon oxide film (SiOₓ), a silicon nitride film (SiNₓ), or a multilayer thereof, but are not necessarily limited thereto. The first, second, and third banks 151, 152, and 153 may also be formed of an organic film, such as an acrylic resin, an epoxy resin, a phenolic resin, a polyamide resin, or a polyimide resin.

The trench T may be formed in the insulating layer 115, the first-first, first-second and first-third electrodes 121, 122, and 123, and the first, second, and third banks 151, 152, and 153. For example, a portion of the trench T may be positioned within the insulating layer 115. The trench T may pass through the first-first, first-second and first-third electrodes 121, 122, and 123, the first, second, and third reflective electrodes 117, 118, and 119, and the first, second, and third banks 151, 152, and 153 between the green, red, and blue sub-pixel regions G, R, and B in the green first sub-pixels SP1, the red second sub-pixels SP2, and the blue third sub-pixels SP3, and may be formed such that a portion of the insulating layer 115 is recessed, but is not necessarily limited thereto. In addition, the trench T may not be formed within the insulating layer 115.

The trench T may be formed to penetrate the insulating layer 115. Hereinafter, for convenience of description, the trench T may indicate a portion which penetrates the first reflective electrode 117, the first-first electrode 121 and the first bank 151 and in which the insulating layer 115 is recessed or penetrated. However, the present disclosure is not limited thereto, and the trench T may similarly appear in the first-second and first-third electrodes 122 and 123, the second and third reflective electrodes 118 and 119, and the second and third banks 152 and 153 of the red and blue sub-pixel regions (R and B in FIG. 4).

More specifically, referring to FIG. 8, the trench T may be formed in a direction from the upper surface of the first bank 151 toward the substrate 111. The trench T may include a first surface T1, a second surface T2, and a third surface T3 connecting the first surface T1 and the second surface T2.

The first surface T1 of the trench T may include a first bank side surface 151a of the first bank 151, a first-first side surface 121a of the first-first electrode 121, a first reflective side surface 117a of the first reflective electrode 117, and a first insulating side surface 115a of the insulating layer 115 provided in the green first sub-pixel regions G, but is not limited thereto. The trench T may be formed to expose the first bank side surface 151a of the first bank 151 provided in the green first sub-pixel regions G. In addition, the trench T may be formed to expose the first-first side surface 121a of the first-first electrode 121 provided in the green first sub-pixel regions G. For example, since the first-first side surface 121a of the first-first electrode 121 provided in the green sub-pixel regions G of one green sub-pixel SP1 may not be covered by the first bank 151 formed at an edge of a first-first upper surface 121b of the first-first electrode 121, the side surface 121a of the first-first electrode 121 may be exposed by the trench T.

The second surface T2 of the trench T may be formed by another sub-pixel disposed adjacent to the one sub-pixel. For example, the second surface T2 may include a second bank side surface 152a of the second bank 152, a first-second side surface 122a of the first-second electrode 122, a second reflective side surface 118a of the second reflective electrode 118, and a second insulating side surface 115b of the insulating layer 115 provided in the red second sub-pixel regions R constituting the red second sub-pixel SP2, but is not limited thereto. The trench T may be formed to expose the second bank side surface 152a of the second bank 152 provided in the red second sub-pixel regions R. In addition, the trench T may be formed to expose the first-second side surface 122a of the first-second electrode 122 and the second reflective side surface 118a of the second reflective electrode 118 provided in the red second sub-pixel regions R. For example, since the first-second side surface 122a of the first-second electrode 122 provided in the red second sub-pixel regions R may not be covered by the second bank 152 formed on an edge of a first-second upper surface 122b of the first-second electrode 122, the first-second side surface 122a of the first-second electrode 122 may be exposed by the trench T.

Further, the third surface T3 of the trench T is provided between the first surface T1 and the second surface T2, and may connect the first surface T1 and the second surface T2. One end of the third surface T3 is connected to the first surface T1, and the other end of the third surface T3 is connected to the second surface T2. The third surface T3 of the trench T may be composed of an inner bottom surface 115c connecting the first insulating side surface 115a and the second insulating side surface 115b of the insulating layer 115.

The first-first, first-second and first-third electrodes 121, 122, and 123 may be formed for each of the green, red, and blue sub-pixel regions G, R, and B within green first sub-pixels SP1, red second sub-pixels SP2, and blue third sub-pixels SP3. In addition, the bank may be formed on the upper edges of each of the first-first, first-second and first-third electrodes 121, 122, and 123 provided in the green, red, and blue sub-pixel regions G, R, and B within the green first sub-pixels SP1, red second sub-pixels SP2, and blue third sub-pixels SP3. Further, the trench T may be formed in the green first sub-pixel regions (G-SP or G in FIG. 4), the red second sub-pixel regions (R-SP or R in FIG. 4), and the blue third sub-pixel regions (B-SP or B in FIG. 4), each of which is partitioned into four areas within the first, second, and third sub-pixels SP1, SP2, and SP3.

The trench T may space apart the first-first, first-second and first-third electrodes 121, 122, and 123 formed in the green, red, and blue sub-pixel regions G, R, and B within the first, second, and third sub-pixels SP1, SP2, and SP3. In addition, the trench T may expose the side surfaces of each of the first-first, first-second and first-third electrodes 121, 122, and 123. In this case, the trench T may have a width equal to a separation length between the first-first, first-second and first-third electrodes 121, 122, and 123. However, the present disclosure is not necessarily limited thereto.

Specifically, the trench T may be provided between the green sub-pixel regions G in the first sub-pixel SP1 and the red sub-pixel regions R in the second sub-pixel SP2. In this case, the trench T may have a width equal to a separation length between the first-first electrode 121 provided in the first sub-pixel SP1 and the first-second electrode 122 provided in the red second sub-pixel SP2. In addition, the trench T may be provided between the red sub-pixel regions R in the second sub-pixel SP2 and the blue sub-pixel regions B in the third sub-pixel SP3. In this case, the trench T may have a width equal to a separation length between the first-second electrode 122 provided in the red sub-pixel regions R of the second sub-pixel SP2 and the first-third electrode 123 provided in the blue sub-pixel regions B of the third sub-pixel SP3. However, embodiments of the present disclosure are not necessarily limited thereto.

Further, the trench T may space apart the first, second, and third banks 151, 152, and 153 formed in the green, red, and blue sub-pixel regions G, R, and B within the first, second, and third sub-pixels SP1, SP2, and SP3, while exposing side surfaces of each of the first, second, and third banks 151, 152, and 153.

In this case, the trench T may have a width equal to a separation length between the first, second, and third banks 151, 152, and 153. Specifically, since the trench T may be disposed between the green sub-pixel regions G in the first sub-pixel SP1 and the red sub-pixel regions R in the second sub-pixel SP2, the trench T may have a width equal to a separation length between the first bank 151 provided in the first sub-pixel SP1 and the second bank 152 provided in the second sub-pixel SP2. In addition, since the trench T may be disposed between the red sub-pixel regions R in the second sub-pixel SP2 and the blue sub-pixel regions B in the third sub-pixel SP3, the trench T may have a width equal to a separation length between the second bank 152 provided in the red sub-pixel regions R and the third bank 153 provided in the blue sub-pixel regions B.

The width of the trench T may be determined by considering the thickness of the EML 132 and a deposition method. When the first organic electroluminescent compound layer 130g is composed of a first hole layer 131g, a first EML 132g, and a first electron layer 133g, the first hole layer 131g and the first EML 132g may be disconnected by the trench T. In this case, the first electron layer 133g may be connected over the trench T. For example, the first electron layer 133g may have a predetermined width so as to be connected over the trench T. Here, the first EML 132g may be a green EML, but is not limited thereto.

When the width of the trench T is formed to be small, the first EML 132g and the second EML 132r of adjacent sub-pixels may be connected to each other. Specifically, the trench T is formed between the green sub-pixel regions G in the first sub-pixel SP1 and the red sub-pixel regions R in the second sub-pixel SP2, and the first hole layer 131g, the first EML 132g, and the first electron layer 133g of the first organic electroluminescent compound layer 130g may be sequentially stacked in the trench T. For example, when the width of the trench T is formed smaller than 0.09 μm, the first hole layer 131g stacked in the green sub-pixel regions G and the second hole layer 131r stacked in the red sub-pixel regions R may be in contact with each other at the upper portion of the trench T. As the first hole layer 131g and the second hole layer 131r become connected between the green sub-pixel regions G and the red sub-pixel regions R, leakage current may occur between adjacent first and second sub-pixels SP1 and SP2. Accordingly, the trench T serves to block the occurrence of leakage current between adjacent green and red sub-pixel regions G and R by securing a predetermined width. Therefore, the trench T prevents the first EML 132g from connecting to the adjacent second EML 132r, thereby blocking leakage current, and this ensures that when the green sub-pixel regions G emit light, it prevents the adjacent red sub-pixel regions R from emitting light unintentionally.

The display device according to the first embodiment of the present disclosure may have a width of the trench T formed to be 0.09 μm or more, so that the first hole layer 131g stacked in the green sub-pixel regions G and the second hole layer 131r stacked in the red sub-pixel regions R may not be in contact with each other at the upper portion of the trench T. However, embodiments of the present disclosure are not necessarily limited thereto. In contrast, when the width of the trench T is formed to be large, the second electrodes 140 of adjacent sub-pixels may be disconnected at the trench T instead of being connected to each other. For example, when the width of the trench T is formed as large as 0.20 μm or more, the second electrode 140 stacked in the green first sub-pixel regions G and the red second sub-pixel regions R may be disconnected by the trench T.

In this case, the second electrode 140 stacked in the green first sub-pixel regions G may be formed on the first surface T1 of the trench T. Also, the second electrode 140 stacked in the red second sub-pixel regions R may be formed on the second surface T2 of the trench T. The first-first side surface 121a of the first-first electrode 121 provided in the green first sub-pixel regions G may still be exposed. In such a case, the first-first side surface 121a of the first-first electrode 121 may be in contact with the second electrode 140, thereby causing a short circuit. For example, when the second electrodes 140 of adjacent sub-pixels are disconnected at the trench T rather than being connected to each other, the first-first side surface 121a of the first-first electrode 121 may be in contact with the second electrode 140, thereby causing a short circuit. Alternatively, the first-second side surface 122a of the first-second electrode 122 provided in the red second sub-pixel regions R may still be exposed. In such a case, the first-second side surface 122a of the first-second electrode 122 may be in contact with the second electrode 140, thereby causing a short circuit. For example, when the second electrodes 140 of adjacent sub-pixels are disconnected at the trench T rather than being connected to each other, the first-second side surface 122a of the first-second electrode 122 may be in contact with the second electrode 140, thereby causing a short circuit.

In order for the second electrode 140 stacked on the green first sub-pixel regions G and the second electrode 140 stacked on the red second sub-pixel regions R to be connected to each other, the display device according to the first embodiment of the present disclosure may have the width W of the trench T formed to be less than 0.20 μm.

For convenience of description, the organic electroluminescent compound layer 130 may be defined as including the first, second and third organic electroluminescent compound layers 130g, 130r, and 130b positioned in each of the green first sub-pixels SP1, red second sub-pixels SP2, and blue third sub-pixels SP3.

The organic electroluminescent compound layer 130 may be formed on the first-first, first-second and first-third electrodes 121, 122, and 123. The organic electroluminescent compound layer 130 may be a white light-emitting layer that emits white light. In this case, the organic electroluminescent compound layer 130 may be a common layer commonly formed in the green, red, and blue sub-pixel regions G, R, and B.

As shown in FIGS. 7 to 9, the organic electroluminescent compound layer 130 may include a hole layer 131, an emission material layer (EML) 132, and an electron layer 133. Here, the hole layer 131 may include a hole injection layer HIL and a hole transport layer HTL, and the electron layer 133 may include an electron transport layer ETL and an electron injection layer EIL.

The organic electroluminescent compound layer 130 may include a first organic electroluminescent compound layer 130g positioned in the green first sub-pixel regions G, a second organic electroluminescent compound layer 130r positioned in the red second sub-pixel regions R, and a third organic electroluminescent compound layer 130b positioned in the blue third sub-pixel regions B.

In addition, the hole layer 131 may include a first hole layer 131g positioned in the green first sub-pixel regions G, a second hole layer 131r positioned in the red second sub-pixel regions R, and a third hole layer 131b positioned in the blue third sub-pixel regions B.

The electron layer 133 is positioned on the upper portion of first, second, and third EMLs 132g, 132r, and 132b, and may be disposed on the entire surface of the green first sub-pixel region G, red second sub-pixel region R, and blue third sub-pixel region B.

Referring to FIG. 7, in order to differentiate first, second and third cavity lengths d1, d2, and d3 between the first, second, and third reflective electrodes 117, 118, and 119 positioned in each of the first, second and third sub-pixel regions G, R, and B and the second electrode 140, the thickness of the first electron layer 133g positioned in the green first sub-pixel regions G may be formed thinner than the thickness of the second electron layer 133r positioned in the red second sub-pixel regions R. In addition, the thickness of the first electron layer 133g may be formed thicker than the thickness of the third electron layer 133b positioned in the blue third sub-pixel regions B. Here, the first, second and third cavity lengths d1, d2, and d3 may be the separation length between the first, second, and third reflective electrodes 117, 118, and 119 and the second electrode 140.

In this case, the thickness of the electron transport layer ETL constituting the first, second, and third electron layers 133g, 133r, and 133b may be formed differently. For example, the first thickness of the electron transport layer ETL positioned in the first sub-pixel SP1, the second thickness of the electron transport layer ETL positioned in the second sub-pixel SP2, and the third thickness of the electron transport layer ETL positioned in the third sub-pixel SP3 may be different from each other. For instance, the first thickness may be thinner than the second thickness and thicker than the third thickness. In this embodiment of the present disclosure, an example is given where the thicknesses of the electron transport layers ETL constituting the electron layer 133 are formed differently, however, the thicknesses of the hole transport layers HTL constituting the hole layer 131 may also be formed differently.

In addition, the EML 132 may include the first EML 132g positioned in the green first sub-pixel regions G and emitting green light, a second EML 132r positioned in the red second sub-pixel regions R and emitting red light, and a third EML 132b positioned in the blue third sub-pixel regions B and emitting blue light. However, the present disclosure is not necessarily limited thereto.

Further, the EML 132 may be formed by sequentially applying first, second, and third fine metal masks (FMMs) (M1, M2, and M3 in FIG. 10A). For example, when forming the first, second, and third sub-pixel regions G, R, and B corresponding to each of the green, red, and blue sub-pixels SP1, SP2 and SP3, the first EML 132g, the second EML 132r, and the third EML 132b may be formed sequentially by applying the first, second, and third fine metal masks (M1, M2, and M3 in FIG. 10A) in order. For instance, with the first fine metal mask (M1 in FIG. 10A) positioned on the upper portion of the first hole layer 131g of the green first sub-pixel regions G, a green light-emitting layer material may be deposited. Accordingly, the first EML 132g may be formed in the green first sub-pixel regions G.

In this case, since each of the plurality of green first sub-pixels SP1 is partitioned into four green sub-pixel regions (G-SP or G in FIG. 4), the first EML 132g may be easily formed using the first fine metal mask M1. Accordingly, the degree of freedom in manufacturing the mask may be improved by four times or more. For example, the display device according to an embodiment of the present disclosure may use the trench T to form the first EML 132g with a width larger than the width of the first-first electrode 121. In this case, since each of the green first sub-pixels SP1 may include trenches T disposed between the four green sub-pixel regions (G-SP or G in FIG. 4), the degree of freedom in designing the mask for forming the first EML 132g may be improved.

Meanwhile, in the case of the red second sub-pixel SP2 and the blue third sub-pixel SP3, the red second EML 132r and the blue third EML 132b may be formed by sequentially using the second and third fine metal masks (M2 and M3 in FIG. 10A), respectively.

Therefore, since each of the plurality of second and third sub-pixels SP2 and SP3 is also partitioned into four red sub-pixel regions (R-SP or R in FIG. 4) and four blue sub-pixel regions (B-SP or B in FIG. 4), the second and third EMLs 132r and 132b may be easily formed by sequentially using the second fine metal mask (M2 in FIG. 10A) and the third fine metal mask (M3 in FIG. 10A), respectively. Accordingly, the degree of freedom in manufacturing the mask may be improved by four times or more.

As shown in FIG. 7, the first EML 132 g formed in the green first sub-pixel regions G, the second EML 132r formed in the red second sub-pixel regions R, and the third EML 132b formed in the blue third sub-pixel regions B may be disconnected from each other by the trench T.

Meanwhile, the first EML 132g formed in the green first sub-pixel regions G and the second EML 132r formed in the red second sub-pixel regions R are not in contact with each other at the upper portion of the trench T.

The first, second, and third EMLs 132g, 132r, and 132b disposed in each of the first, second, and third sub-pixel regions G, R, and B may be disconnected from each other within the trench T. Accordingly, it may be difficult for charges to migrate through the first, second, and third EMLs 132g, 132r, and 132b between adjacent green, red, and blue sub-pixel regions G, R, and B.

The first, second and third organic electroluminescent compound layers 130g, 130r, and 130b according to an embodiment of the present disclosure may minimize mutual interference caused by leakage current between adjacent first, second, and third sub-pixels SP1, SP2, and SP3 through the trench T.

In this way, excitons may be formed during the excitation process when holes and electrons, injected from the first-first, first-second and first-third electrodes 121, 122, and 123 (which are anode electrodes) and the second electrode 140 (which is a cathode electrode) facing each other with the first, second and third organic electroluminescent compound layers 130g, 130r, and 130b interposed therebetween, recombine in the EMLs 132g, 132r, and 132b. Accordingly, the first, second and third organic electroluminescent compound layers 130g, 130r, and 130b may emit light due to the energy from the excitons. In particular, the organic light-emitting display device may display images by electrically controlling the amount of light generated in the first, second, and third EMLs 132g, 132r, and 132b.

Meanwhile, the second electrode 140 is formed on the upper portion of the first, second and third organic electroluminescent compound layers 130g, 130r, and 130b. The second electrode 140 may be a common layer formed commonly across the first, second, and third sub-pixel regions G, R, and B.

This second electrode 140 may be made of a transparent metal material, a semi-transmissive metal material, or a metal material with high reflectivity.

When the display device is configured as a top emission type, the second electrode 140 may be formed of a transparent conductive oxide (TCO) such as an indium tin oxide (ITO) or an indium zinc oxide (IZO) which may transmit light, or a semi-transmissive conductive material such as magnesium (Mg), silver (Ag), or an alloy of magnesium (Mg) and silver (Ag). When the display device is configured as a bottom emission type, the second electrode 140 may be formed of a metal material with high reflectivity, such as a stacked structure of aluminum and titanium (Ti/Al/Ti), a stacked structure of aluminum and ITO (ITO/Al/ITO), an Ag alloy, or a stacked structure of an Ag alloy and ITO (ITO/Ag alloy/ITO). This second electrode 140 may be a cathode electrode.

Referring to FIGS. 7 to 9, the first cavity length d1 between the first reflective electrode 117 positioned in the green sub-pixel regions G within the first sub-pixel SP1 and the second electrode 140 may be shorter than the second cavity length d2 between the second reflective electrode 118 positioned within the red sub-pixel regions R in the second sub-pixel SP2 and the second electrode 140. Also, the first cavity length d1 may be formed longer than the third cavity length d3 between the third reflective electrode 119 positioned within the blue sub-pixel regions B in the third sub-pixel SP3 and the second electrode 140.

In particular, the wavelengths of red, green, and blue light may be in the order of red light>green light>blue light. Accordingly, the cavity lengths for red, green, and blue light may also be in the order of red light>green light>blue light. That is, a transmittance peak corresponding to red light may appear at a longer wavelength band compared to green light and blue light.

Accordingly, the first cavity length d1 between the first reflective electrode 117 positioned in the green first sub-pixel regions G within the first sub-pixel SP1 and the second electrode 140 may be shorter than the second cavity length d2 between the second reflective electrode 118 positioned in the red second sub-pixel regions R within the red second sub-pixel SP2 and the second electrode 140. Further, the first cavity length d1 may be longer than the third cavity length d3 between the third reflective electrode 119 positioned in the blue third sub-pixel regions B within the blue third sub-pixel SP3 and the second electrode 140.

The capping layer 160 and the encapsulation film 170 may be formed on the upper portion of the second electrode 140. The capping layer 160 and the encapsulation film 170 may be protective layers to protect the plurality of the first, second and third organic electroluminescent compound layers 130g, 130r, and 130b and the second electrode 140 from moisture (H₂O ) and the like penetrating from the outside.

The encapsulation film 170 serves to prevent oxygen or moisture from penetrating into the first, second and third organic electroluminescent compound layers 130g, 130r, and 130b and the second electrode 140. To this end, the encapsulation film 170 may include at least one inorganic film and at least one organic film. For example, a first inorganic film may be formed to cover the second electrode 140. The organic film is formed on the first inorganic film with sufficient thickness to prevent particles from penetrating the first inorganic film and entering the first, second and third organic electroluminescent compound layers 130g, 130r, and 130b and the second electrode 140. Additionally, a second inorganic film may be formed to cover the organic film.

Each of the first and second inorganic films may be formed of silicon nitride, aluminum nitride, zirconium nitride, titanium nitride, hafnium nitride, tantalum nitride, silicon oxide, aluminum oxide, or titanium oxide. The organic film may be formed of acrylic resin, epoxy resin, phenolic resin, polyamide resin, or polyimide resin. The manufacturing method of the display device according to the first embodiment of the present disclosure may be described with reference to the following attached drawings.

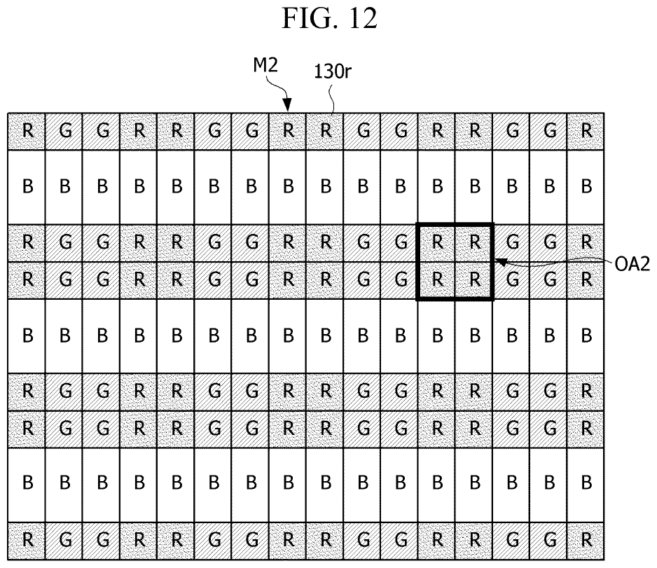

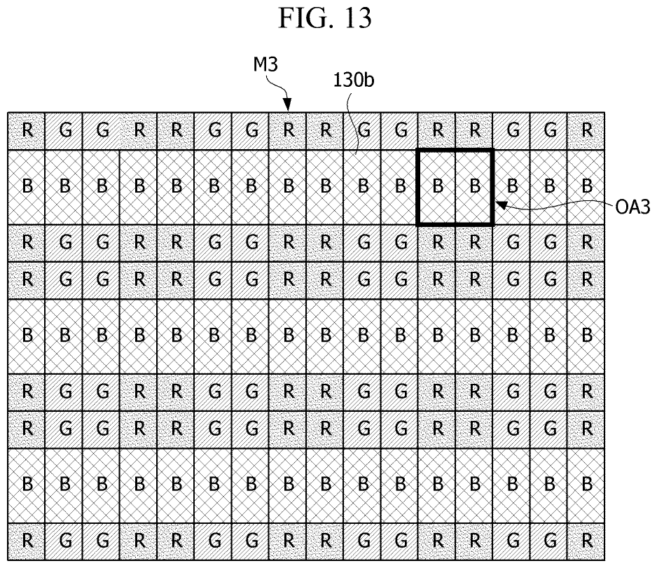

FIGS. 10A and 10B are cross-sectional views illustrating a manufacturing method of a display device according to the first embodiment of the present disclosure. FIG. 11 is a plan view illustrating a case where a first mask for forming a green EML is applied to form a green EML G-EML in green sub-pixel regions in the display device according to the first embodiment of the present disclosure; FIG. 12 is a plan view illustrating a case where a second mask for forming a red EML is applied to form a red EML R-EML in red sub-pixel regions in the display device according to the first embodiment of the present disclosure; FIG. 13 is a plan view illustrating a case where a third mask for forming a blue EML is applied to form a blue EML B-EML in blue sub-pixel regions in the display device according to the first embodiment of the present disclosure. Although not shown in FIGS. 10 to 13, the first substrate 111 is defined into a display area DA and a non-display area NDA, and a pad area PA where pads are formed may be disposed in the non-display area NDA.

In the display area DA, the data lines and gate lines intersecting the data lines are formed. In addition, in the display area DA, sub-pixels 10 for displaying an image in a matrix form may be formed at intersection areas of the data lines and the gate lines.

The sub-pixels 10 may include the green first sub-pixel SP1, the red second sub-pixel SP2, and the blue third sub-pixel SP3. The green first sub-pixel SP1 may be configured to discharge green light, the red second sub-pixel SP2 to discharge red light, and the blue third sub-pixel SP3 to discharge blue light. However, it is not necessarily limited thereto. The sub-pixels 10 may further be provided with a fourth sub-pixel which discharges white light. Additionally, the arrangement order of the first, second and third sub-pixels SP1, SP2 and SP3 may be varied in various ways.

Referring to the previously described FIGS. 3 and 4, the green first sub-pixel SP1 is partitioned into four first sub-pixel regions (SP1-1, SP1-2, SP1-3, and SP1-4 in FIG. 3, or G-SP or G in FIG. 4), and the red second sub-pixel SP2 is partitioned into four second sub-pixel regions (SP2-1, SP2-2, SP2-3, and SP2-4 in FIG. 3, or R-SP or R in FIG. 4). The blue third sub-pixel SP3 may be partitioned into four third sub-pixel regions (SP3-1, SP3-2, SP3-3, and SP3-4 in FIG. 3, or B-SP or B in FIG. 4).

Hereinafter, the description will be focused on two green, red, and blue sub-pixel regions among the four green, red, and blue sub-pixel regions of the first, second and third sub-pixels SP1, SP2, and SP3.

The first substrate 111 may be made of glass or plastic, but is not necessarily limited thereto, and may be made of a semiconductor material such as a silicon wafer. The first substrate 111 may be made of a transparent material or an opaque material.

The display device according to the first embodiment of the present disclosure may be configured as a top emission type in which emitted light is discharged toward the upper portion, but is not necessarily limited thereto. When the display device is configured as the top emission type in which emitted light is discharged toward the upper portion, the first substrate 111 may be formed of transparent materials or opaque materials. In contrast, when the display device is configured as a so-called bottom emission type in which emitted light is discharged toward the lower portion, the first substrate 111 may be formed of a transparent material.

Referring to FIG. 10A, circuit elements including various signal lines, thin-film transistors, and capacitors may be formed on the first substrate 111 for each of the green, red, and blue sub-pixel regions G, R, and B within the first, second, and third sub-pixels SP1, SP2, and SP3. The signal lines may include gate lines, data lines, power lines, and reference lines, and the thin-film transistors may include switching thin-film transistors, driving transistors TFT, and sensing thin-film transistors.

Next, an insulating layer 115 may be formed on the circuit elements including the driving transistor TFT. The insulating layer 115 may be formed of an inorganic film, for example, a silicon oxide film (SiOₓ), a silicon nitride film (SiNₓ), or a multilayer thereof, but is not necessarily limited thereto.

Next, a reflective electrode-forming material layer for forming the first, second and third reflective electrodes 117, 118, and 119 and a first electrode-forming material layer for forming the first-first, first-second and first-third electrodes 121, 122, and 123 may be stacked on the insulating layer 115.

Subsequently, a bank-forming material layer (not shown) for forming the first, second and third banks 151, 152, and 153 is formed on the upper portion of the first electrode-forming material layer, and the bank-forming material layer (not shown) is selectively patterned to expose a portion of the first electrode-forming material layer. In this case, the exposed portion of the first electrode-forming material layer may correspond to the emission area (EA in FIG. 7).

Next, the bank-forming material layer and the underlying first electrode-forming material layer and the reflective electrode-forming material layer are sequentially etched to form the first, second and third banks 151, 152, and 153, the first-first, first-second and first-third electrodes 121, 122, and 123, and the first, second, and third reflective electrodes 117, 118, and 119.

In this case, the first, second, and third reflective electrodes 117, 118, and 119 and the first-first, first-second and first-third electrodes 121, 122, and 123 may be respectively formed on the insulating layer 115 for each of the first, second and third sub-pixels SP1, SP2, and SP3.

The first sub-pixel SP1 may be partitioned into four green sub-pixel regions (SP1-1, SP1-2, SP1-3, and SP1-4 in FIG. 3, or G-SP or G in FIG. 4), and the first reflective electrode 117 and the first-first electrode 121 may be respectively formed in each of the partitioned four green sub-pixel regions (G-SP or G in FIG. 4).

In addition, the second sub-pixel SP2 may be partitioned into four red sub-pixel regions (SP2-1, SP2-2, SP2-3, and SP2-4 in FIG. 3, or R-SP or R in FIG. 4), and the second reflective electrode 118 and the first-second electrode 122 may be respectively formed in each of the partitioned four red sub-pixel regions (R-SP or R in FIG. 4).

Further, the third sub-pixel SP3 may be partitioned into four blue sub-pixel regions (SP3-1, SP3-2, SP3-3, and SP3-4 in FIG. 3, or B-SP or B in FIG. 4), and the third reflective electrode 119 and the first-third electrode 123 may be respectively formed in each of the partitioned four blue sub-pixel regions (B-SP or B in FIG. 4).

In this case, the first, second, and third reflective electrodes 117, 118, and 119 may serve as reflectors which reflect light discharged from the first, second and third organic electroluminescent compound layers 130g, 130r, and 130b. For example, the first, second, and third reflective electrodes 117, 118, and 119 may be formed of silver (Ag), aluminum (Al), molybdenum (Mo), an alloy of silver (Ag) and magnesium (Mg), or an alloy of these materials, all of which have high electrical conductivity and a low work function.

The first-first, first-second and first-third electrodes 121, 122, and 123 may be connected to the driving transistor TFT. Specifically, since the first-first, first-second and first-third electrodes 121, 122, and 123 are connected to a source terminal or a drain terminal of the driving transistor TFT through a contact hole CH penetrating the insulating layer 115, a voltage for emitting light may be applied to the first-first, first-second and first-third electrodes 121, 122, and 123. The first-first, first-second and first-third electrodes 121, 122, and 123 may be made of at least one of a transparent metal material, a transflective metal material, and a metal material having high reflectivity.

In a case where the display device is configured as a top emission type, the first-first, first-second and first-third electrodes 121, 122, and 123 may be made of a metal material having high reflectivity or a stacked structure of a metal material having high reflectivity and a transparent metal material.

In a case where the display device is configured as a bottom emission type, the first-first, first-second and first-third electrodes 121, 122, and 123 may be formed of a transparent conductive oxide (TCO) such as an indium tin oxide (ITO) or an indium zinc oxide (IZO) which may transmit light, or a semi-transmissive conductive material such as magnesium (Mg), silver (Ag), or an alloy of magnesium (Mg) and silver (Ag). The first-first, first-second and first-third electrodes 121, 122, and 123 may be anode electrodes.

The first, second, and third banks 151, 152, and 153 are formed on the first-first, first-second and first-third electrodes 121, 122, and 123 to define the emission areas (EA in FIG. 7) for each of the plurality of first, second, and third sub-pixel regions G, R, and B. That is, when the first, second, and third banks 151, 152, and 153 are not formed to cover entire areas of the first-first, first-second and first-third electrodes 121, 122, and 123 in each of the first, second, and third sub-pixel regions G, R, and B, the exposed areas of the first-first, first-second and first-third electrodes 121, 122, and 123 may become the emission areas (EA in FIG. 7). In contrast, an area excluding the emission area EA may be a non-emission area.

In addition, the first bank 151 may define the emission area EA for each of the first-first to first-fourth sub-pixel regions (SP1-1, SP1-2, SP1-3, and SP1-4 in FIG. 3, or G-SP or G in FIG. 4) partitioned within the first sub-pixel SP1. The first-first to first-fourth sub-pixel regions may be collectively referred to as the first sub-pixel regions.

Further, the second bank 152 may define the emission area EA for each of the second-first to second-fourth sub-pixel regions (SP2-1, SP2-2, SP2-3, and SP2-4 in FIG. 3, or R-SP or R in FIG. 4) partitioned within the second sub-pixel SP2. The second-first to second-fourth sub-pixel regions may be collectively referred to as the second sub-pixel regions.

In addition, the third bank 153 may define the emission area EA for each of the third-first to third-fourth sub-pixel regions (SP3-1, SP3-2, SP3-3, and SP3-4 in FIG. 3, or B-SP or B in FIG. 4) partitioned within the third sub-pixel SP3. The third-first to third-fourth sub-pixel regions may be collectively referred to as the third sub-pixel regions. In this case, the first, second, and third banks 151, 152, and 153 are formed on the edges of the first-first, first-second and first-third electrodes 121, 122, and 123 to prevent a decrease in luminous efficiency caused by a current concentration at the ends of the first-first, first-second and first-third electrodes 121, 122, and 123.

The first, second, and third banks 151, 152, and 153 may be formed of an inorganic film, for example, a silicon oxide film (SiOₓ), a silicon nitride film (SiNₓ), or a multilayer thereof, but are not necessarily limited thereto. The first, second and third banks 151, 152, and 153 may also be formed of an organic film, such as an acrylic resin, an epoxy resin, a phenolic resin, a polyamide resin, or a polyimide resin.

The trench T may be formed in the insulating layer 115, the first, second, and third reflective electrodes 117, 118, and 119, the first-first, first-second and first-third electrodes 121, 122, and 123, and the first, second and third banks 151, 152, and 153. The trench T may be formed to penetrate the first, second, and third reflective electrodes 117, 118, and 119, the first-first, first-second and first-third electrodes 121, 122, and 123, and the first, second and third banks 151, 152, and 153 between the first, second and third sub-pixels SP1, SP2, and SP3, such that a portion of the insulating layer 115 is recessed, although it is not necessarily limited to this structure. The trench T may be formed to penetrate the insulating layer 115. Hereinafter, for convenience of explanation, the trench T may refer to a portion which penetrates the first-first, first-second and first-third electrodes 121, 122, and 123 and the first, second and third banks 151, 152, and 153, while recessing or penetrating the insulating layer 115.

More specifically, the trench T may be formed in a direction from the upper surface of the first, second and third banks 151, 152, and 153 toward the substrate 111.

Next, in order to form the first, second and third organic electroluminescent compound layers 130g, 130r, and 130b in FIG. 10B on the first-first, first-second and first-third electrodes 121, 122, and 123, the first, second and third hole layers 131g, 131r, and 131b may be formed first. In this case, the first, second and third organic electroluminescent compound layers 130g, 130r, and 130b may be white light-emitting layers which emit white light. In this case, the first, second and third organic electroluminescent compound layers 130g, 130r, and 130b may be common layers formed commonly on the first, second and third sub-pixels SP1, SP2, and SP3.

Subsequently, in order to form the first, second, and third EMLs 132g, 132r, and 132b on the first, second and third hole layers 131g, 131r, and 131b within the first, second, and third sub-pixels SP1, SP2, and SP3, a process may be performed to sequentially arrange first, second, and third fine metal masks (FMMs) M1, M2, and M3 on the sub-pixel regions G, R, and B within the first, second, and third sub-pixels SP1, SP2, and SP3, and then form the first, second, and third EMLs 132g, 132r, and 132b according to the sequential arrangement order.

For example, a process of forming the first EML 132g may be performed while the first fine metal mask M1 is first disposed. Subsequently, after removing the first fine metal mask M1, a process of forming the second EML 132r may be performed while the second fine metal mask M2 is disposed. Next, after removing the second fine metal mask M2, a process of forming the third EML 132b may be performed while the third fine metal mask M3 is disposed. However, embodiments of the present disclosure are not limited thereto.

Specifically, referring to FIGS. 10A and 11, the first fine metal mask M1 may include first opening areas OA1 exposing portions of the first hole layer 131g positioned within the four sub-pixel regions G disposed in the first sub-pixel SP1. In this case, the first opening areas OA1 may overlap the partitioned four sub-pixel regions of the first sub-pixel SP1, for example, the first-first to first-fourth sub-pixel regions (SP1-1, SP1-2, SP1-3, and SP1-4 in FIG. 3, or G-SP or G in FIG. 4).

In addition, referring to FIGS. 10A and 12, the second fine metal mask M2 may include second opening areas OA2 exposing portions of the second hole layer 131r within the four sub-pixel regions R disposed in the second sub-pixel SP2. In this case, the second opening areas OA2 may overlap the partitioned four sub-pixel regions of the second sub-pixel SP2, for example, the second-first to second-fourth sub-pixel regions (SP2-1, SP2-2, SP2-3, and SP2-4 in FIG. 3, or R-SP or R in FIG. 4).

Further, referring to FIGS. 10A and 13, the third fine metal mask M3 may include third opening areas OA3 exposing portions of the third hole layer 131b within the four sub-pixel regions B disposed in the third sub-pixel SP3. In this case, the third opening areas OA3 may overlap the partitioned four sub-pixel regions of the third sub-pixel SP3, for example, the third-first to third-fourth sub-pixel regions (SP3-1, SP3-2, SP3-3, and SP3-4 in FIG. 3, or B-SP or B in FIG. 4).

Next, the first, second, and third EMLs 132g, 132r, and 132b may be sequentially formed on the first, second, and third hole layers 131g, 131r, and 131b using the first, second, and third fine metal masks M1, M2, and M3.

In addition, the EML 132 may include the first EML 132g positioned in the first sub-pixel regions G within the first sub-pixel SP1 to emit green light, a second EML 132r positioned in the second sub-pixel regions R within the second sub-pixel SP2 to emit red light, and a third EML 132b positioned in the third sub-pixel regions B within the third sub-pixel SP3 to emit blue light. However, the present disclosure is not necessarily limited thereto.

Specifically, each of the first EML 132g, the second EML 132r, and the third EML 132b may be sequentially formed using the aforementioned first, second, and third fine metal masks (FMMs) M1, M2, and M3.

For example, referring to FIGS. 10A and 11, in order to form the first EML 132g in the first sub-pixel SP1 among the first, second, and third sub-pixels SP1, SP2, and SP3, a green light-emitting layer material may be deposited while the first fine metal mask M1 is disposed on the upper portion of the first hole layers 131g of the plurality of first-first to first-fourth sub-pixel regions (SP1-1, SP1-2, SP1-3, and SP1-4 in FIG. 3, or G-SP or G in FIG. 4). Accordingly, the green first EMLs 132g may be simultaneously formed in the first-first to first-fourth sub-pixel regions (SP1-1, SP1-2, SP1-3, and SP1-4 in FIG. 3, or G-SP or G in FIG. 4).

In addition, referring to FIGS. 10A and 12, a red light-emitting layer material may be deposited while the second fine metal mask M2 is disposed on the upper portion of the second hole layer 131r of the second-first to second-fourth sub-pixel regions (SP2-1, SP2-2, SP2-3, and SP2-4 in FIG. 3, or R-SP or R in FIG. 4) constituting the second sub-pixel SP2. Accordingly, the red second EMLs 132r may be simultaneously formed in the second sub-pixel regions (SP2-1, SP2-2, SP2-3, and SP2-4 in FIG. 3, or R-SP or R in FIG. 4).

Further, referring to FIGS. 10A and 13, a blue light-emitting layer material may be deposited while the third fine metal mask M3 is disposed on the upper portion of the third hole layer 131b of the third-first to third-fourth sub-pixel regions (SP3-1, SP3-2, SP3-3, and SP3-4 in FIG. 3, or B-SP or B in FIG. 4) constituting the third sub-pixel SP3. Accordingly, the blue third EMLs 132b may be simultaneously formed in the third-first to third-fourth sub-pixel regions (SP3-1, SP3-2, SP3-3, and SP3-4 in FIG. 3, or B-SP or B in FIG. 4). In this case, the order of forming the first, second, and third EMLs 132g, 132r, and 132b is not limited thereto.

Subsequently, the first, second, and third electron layers 133g, 133r, and 133b may be formed on the entire surface of the first substrate 111 including the first, second, and third EMLs 132g, 132r, and 132b. In this case, as shown in FIGS. 5 and 7, the first, second and third organic electroluminescent compound layers 130g, 130r, and 130b may include the first, second, and third hole layers 131g, 131r, and 131b composed of a hole injection layer HIL and a hole transport layer HTL, the first, second, and third emission material layers (EMLs) 132g, 132r, and 132b, and the first, second, and third electron layers 133g, 133r, and 133b composed of an electron transport layer ETL and an electron injection layer EIL.

The organic electroluminescent compound layer 130 may include a first organic electroluminescent compound layer 130g positioned in the first sub-pixel SP1, a second organic electroluminescent compound layer 130r positioned in the second sub-pixel SP2, and a third organic electroluminescent compound layer 130b positioned in the third sub-pixel SP3.

The hole layer 131 may include a first hole layer 131g positioned in the first sub-pixel SP1, a second hole layer 131r positioned in the second sub-pixel SP2, and a third hole layer 131b positioned in the third sub-pixel SP3.

The electron layer 133 is positioned on the upper portion of the EML 132 and may be disposed on the entire surface of the first, second and third sub-pixel regions G, R, and B of the first, second, and third sub-pixels SP1, SP2, and SP3. The electron layer 133 may include a first electron layer 133g positioned in the first sub-pixel SP1, a second electron layer 133r positioned in the second sub-pixel SP2, and a third electron layer 133b positioned in the third sub-pixel SP3.

In order to differentiate the first, second and third cavity lengths d1, d2, and d3 between the second electrode 140 and the first, second, and third reflective electrodes 117, 118, and 119 positioned in each of the first, second and third sub-pixel SP1, SP2, and SP3, the thickness of the first electron layer 133g positioned in the first sub-pixel regions G within the first sub-pixel SP1 may be formed thinner than the thickness of the second electron layer 133r positioned in the second sub-pixel regions R within the second sub-pixel SP2, and thicker than the thickness of the third electron layer 133b positioned in the third sub-pixel regions B within the third sub-pixel SP3.

In this case, the thicknesses of the electron transport layers ETL constituting the first, second, and third electron layers 133g, 133r, and 133b may be formed differently. Although this embodiment of the present disclosure illustrates a case where the thicknesses of the electron transport layers ETL constituting the electron layer 133 are formed differently, the thicknesses of the hole transport layers HTL constituting the hole layer 131 may also be formed differently.

As described above, each of the plurality of first, second, and third sub-pixels SP1, SP2, and SP3 may also be partitioned into four green sub-pixel regions SP1-1, SP1-2, SP1-3, and SP1-4, four red sub-pixel regions SP2-1, SP2-2, SP2-3, and SP2-4, and four blue sub-pixel regions SP3-1, SP3-2, SP3-3, and SP3-4, respectively.

Accordingly, the first, second, and third EMLs 132g, 132r, and 132b may be easily formed in the four green, red, and blue sub-pixel regions disposed in each of the plurality of first, second, and third sub-pixels SP1, SP2, and SP3 by sequentially using the first, second, and third fine metal masks M1, M2, and M3, thereby improving the degree of freedom in manufacturing the mask by four times or more.

Further, as shown in FIG. 7, the first EML 132g formed in the first sub-pixel regions G, the second EML 132r formed in the second sub-pixel regions R, and the third EML 132b formed in the third sub-pixel regions B may be disconnected from each other due to the step height of the trench T.

Meanwhile, the first EML 132g formed in the first sub-pixel regions G and the second EML 132r formed in the second sub-pixel regions R may not be in contact with each other on the upper portion of the trench T.

Accordingly, since the first, second, and third EMLs 132g, 132r, and 132b disposed in each of the first, second, and third sub-pixel regions G, R, and B are disconnected from each other through the trench T, it may be difficult for charges to migrate through the first, second, and third EMLs 132g, 132r, and 132b between adjacent sub-pixel regions (G, R, and B). Accordingly, the first, second and third organic electroluminescent compound layers 130g, 130r, and 130b according to the first embodiment of the present disclosure may minimize the problem of the first, second, and third sub-pixel regions G, R, and B, which are disposed adjacent to each other, being affected by leakage current through the first, second, and third EMLs 132g, 132r, and 132b.

Next, the electron layer 133 may be formed on the upper portion of the first substrate 111 including the first, second, and third EMLs 132g, 132r, and 132b. In this case, the electron layer 133 is positioned on the upper portion of the EML 132 and is disposed on the entire surface of the first, second, and third sub-pixel regions G, R, and B. Further, the electron layer 133 may include a first electron layer 133g positioned in the first sub-pixel regions G, a second electron layer 133r positioned in the second sub-pixel regions R, and a third electron layer 133b positioned in the third sub-pixel regions B.

In order to differentiate first, second and third cavity lengths d1, d2, and d3 between the second electrode 140 and the first, second, and third reflective electrodes 117, 118, and 119 positioned in the first, second and third sub-pixel regions G, R, and B, the thickness of the first electron layer 133g positioned in the first sub-pixel regions G may be formed thinner than the thickness of the second electron layer 133r positioned in the second sub-pixel regions R, and thicker than the thickness of the third electron layer 133b positioned in the third sub-pixel regions B.

In this case, the thickness of the electron transport layer ETL constituting the first, second, and third electron layers 133g, 133r, and 133b may be formed differently. Although this embodiment of the present disclosure illustrates a case where the thicknesses of the electron transport layers ETL constituting the electron layer 133 are formed differently, the thicknesses of the hole transport layers HTL constituting the hole layer 131 may also be formed differently.

Next, referring to FIG. 7, a second electrode 140 is formed on the organic electroluminescent compound layer 130. The second electrode 140 may be a common layer commonly formed in the first, second, and third sub-pixel regions G, R, and B.

This second electrode 140 may be made of a transparent metal material, a transflective metal material, or a metal material with high reflectivity.

In this case, the first cavity length d1 between the first reflective electrode 117 positioned in the first sub-pixel regions G and the second electrode 140 may be formed shorter than the second cavity length d2 between the second reflective electrode 118 positioned in the second sub-pixel regions R and the second electrode 140, and longer than the third cavity length d3 between the third reflective electrode 119 positioned in the third sub-pixel regions B and the second electrode 140.

In particular, the wavelength length for red, green, and blue light may be in the order of red light>green light>blue light. Accordingly, the cavity lengths for red, green, and blue light may also be in the order of red light>green light>blue light. That is, since the wavelength band of red light implements a longer wavelength band than those of the green and blue light, a transmittance peak may appear at a longer wavelength band compared to the green light and blue light.

Therefore, the first cavity length d1 between the first reflective electrode 117 positioned in the first sub-pixel regions G and the second electrode 140 may be formed shorter than the second cavity length d2 between the second reflective electrode 118 positioned in the second sub-pixel regions R and the second electrode 140, and longer than the third cavity length d3 between the third reflective electrode 119 positioned in the third sub-pixel regions B and the second electrode 140.

Next, the capping layer 160 and the encapsulation film 170 may be formed on the upper portion of the second electrode 140. Since the capping layer 160 and the encapsulation film 170 protect the plurality of organic electroluminescent compounds 130 and the second electrode 140 from moisture (H₂O ) and the like penetrating from the outside, the capping layer 160 and the encapsulation film 170 may be protective layers.

The encapsulation film 170 may serve to prevent oxygen or moisture from penetrating into the organic electroluminescent compound layer 130 and the second electrode 140. To this end, the encapsulation film 170 may include at least one inorganic film and at least one organic film. Specifically, the encapsulation film 170 may include a first inorganic film and an organic film. In one embodiment, the encapsulation film 170 may further include a second inorganic film.

The first inorganic film may be formed to cover the second electrode 140. The organic film is formed on the first inorganic film and may be formed with a sufficient thickness to prevent particles from penetrating the first inorganic film and reaching the organic electroluminescent compound layer 130 and the second electrode 140. The second inorganic film may be formed to cover the organic film.

In this way, the first embodiment of the present disclosure may implement six pixels (PX1, PX2, PX3, PX4, PX5, and PX6 in FIG. 4) by combining the first, second, and third sub-pixel regions R-SP, G-SP, and B-SP.

Hereinafter, a display device according to a second embodiment of the present disclosure will be described.

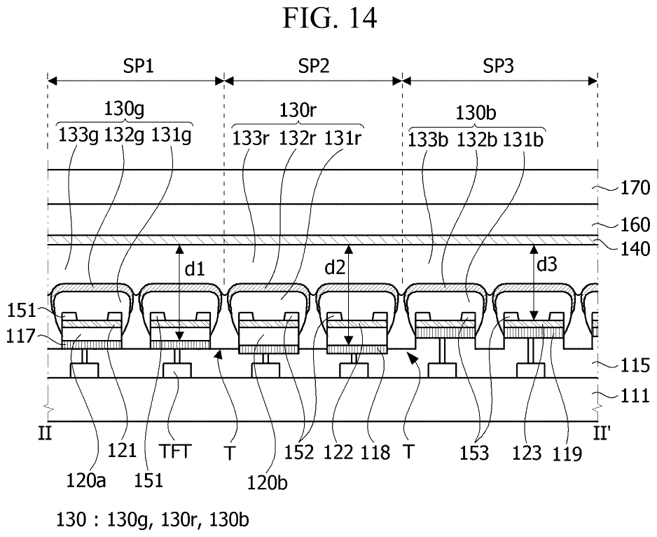

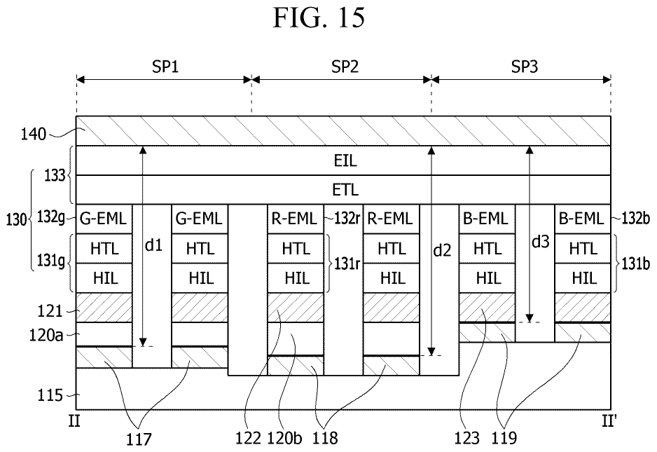

FIG. 14 is a cross-sectional view taken along line II-II′ of FIG. 4 as a second embodiment of the present disclosure. FIG. 15 is a cross-sectional view schematically illustrating an example of the configurations of a first electrode, a light-emitting layer, and a second electrode in each of two sub-pixel regions within green, red, and blue sub-pixels in a display device according to the second embodiment of the present disclosure.

Here, among the components of the second embodiment of the present disclosure in FIG. 14, the remaining components except for some components may be the same as the components of the first embodiment of the present disclosure illustrated in FIG. 7. Therefore, descriptions of the same components as those of the first embodiment of the present disclosure among the components of the second embodiment of the present disclosure will be omitted.

The first, second and third cavity lengths d1, d2, and d3 between the first, second, and third reflective electrodes 117, 118, and 119 and the second electrode 140 in the second embodiment of the present disclosure shown in FIG. 14 may be differently defined from the first, second and third cavity lengths d1, d2, and d3 between the first, second, and third reflective electrodes 117, 118, and 119 and the second electrode 140 in the first embodiment shown in FIG. 7. Additionally, the thickness of the electron layer 133 of the organic electroluminescent compound layer 130 constituting the second embodiment of the present disclosure shown in FIG. 14 may be different from the thickness of the electron layer 133 of the organic electroluminescent compound layer 130 constituting the first embodiment shown in FIG. 7.

Referring to FIGS. 14 and 15, the insulating layer 115 may be formed such that the portions positioned in the first, second and third sub-pixel regions G, R, and B within the first, second, and third sub-pixels SP1, SP2, and SP3 have different thicknesses. For example, the thickness of the portion of the insulating layer 115 positioned in the first sub-pixel regions G within the first sub-pixel SP1 may be formed thicker than the portion of the insulating layer 115 positioned in the second sub-pixel regions R within the second sub-pixel SP2, and thinner than the portion of the insulating layer 115 positioned in the third sub-pixel regions B within the third sub-pixel SP3. This is to differentiate the first, second and third cavity lengths d1, d2, and d3 between the first, second, and third reflective electrodes 117, 118, and 119 and the second electrode 140. That is, since the wavelengths of red light, green light, and blue light is in the order of red light>green light>blue light, the second, first and third cavity lengths d2, d1, and d3 should also be disposed in the order of red light>green light>blue light.

The first, second, and third reflective electrodes 117, 118, and 119 may be respectively formed on areas of the insulating layer 115 having different thicknesses at different positions. The third reflective electrode 119 may be formed on an area of the insulating layer 115 having the thickest thickness. The second reflective electrode 118 may be formed on an area of the insulating layer 115 having the thinnest thickness. In addition, the first reflective electrode 117 may be formed on the area of the insulating layer 115 having an intermediate thickness. In this case, the thicknesses of the first, second and third reflective electrodes 117, 118, and 119 may be different from each other, but are not limited thereto.

Further, first and second auxiliary insulating layers 120a and 120b may be formed on the first and second reflective electrodes 117 and 118, respectively. For example, the first auxiliary insulating layer 120a may be disposed on the first reflective electrode 117, and the second auxiliary insulating layer 120b may be disposed on the second reflective electrode 118. The trench T may be formed to penetrate the first and second auxiliary insulating layers 120a and 120b.

In addition, the first-first, first-second and first-third electrodes 121, 122, and 123 may be formed on the first and second auxiliary insulating layers 120a and 120b and the third reflective electrode 119, respectively. For instance, the first-first electrode 121 of the first sub-pixel SP1 may be disposed on the first auxiliary insulating layer 120a. Additionally, the first-second electrode 122 of the second sub-pixel SP2 may be disposed on the second auxiliary insulating layer 120b. Additionally, the first-third electrode 123 of the third sub-pixel SP3 may be disposed on the third reflective electrode 119. In this case, the thickness of the second auxiliary insulating layer 120b may be greater than the thickness of the first auxiliary insulating layer 120a, but it is not limited thereto.

Referring to FIGS. 14 and 15, in order to differentiate the first, second and third cavity lengths d1, d2, and d3 between the first, second, and third reflective electrodes 117, 118, and 119 positioned in the first, second and third sub-pixel regions G, R, and B within each of the first, second and third sub-pixel SP1, SP2, and SP3 and the second electrode 140, the thickness of a portion of the insulating layer 115 positioned in the first sub-pixel regions G within the first sub-pixel SP1 may be formed thicker than the thickness of a portion of the insulating layer 115 positioned in the second sub-pixel regions R within the second sub-pixel SP2, and thinner than the thickness of a portion of the insulating layer 115 positioned in the third sub-pixel regions B within the third sub-pixel SP3.

In addition, the first, second and third EMLs 132g, 132r, and 132b may be sequentially formed by applying masks for forming the EMLs, for example, the first, second, and third fine metal masks M1, M2, and M3 in FIGS. 10A and 11 to 13.

Accordingly, each of the plurality of first, second, and third sub-pixels SP1, SP2, and SP3 may be partitioned into four first-first to first-fourth sub-pixel regions (SP1-1, SP1-2, SP1-3, and SP1-4 in FIG. 3, or G-SP or G in FIG. 4), second-first to second-fourth sub-pixel regions (SP2-1, SP2-2, SP2-3, and SP2-4 in FIG. 3, or R-SP or R in FIG. 4), and third-first to third-fourth sub-pixel regions (SP3-1, SP3-2, SP3-3, and SP3-4 in FIG. 3, or B-SP or B in FIG. 4). Therefore, since the first, second and third EMLs 132g, 132r, and 132b may be sequentially formed using the first, second and third fine metal masks M1, M2, and M3, the degree of freedom in manufacturing the fine metal mask (FMM) may be improved by four times or more.

In addition, similar to the first embodiment, the first EML 132g formed in the first sub-pixel regions G, the second EML 132r formed in the second sub-pixel regions R, and the third EML 132b formed in the third sub-pixel regions B may be disconnected from each other due to the step height of the trench T.

Further, the first EML 132g formed in the first sub-pixel regions G and the second EML 132r formed in the second sub-pixel regions R may not be in contact with each other at the upper portion of the trench T.

Since the first, second, and third EMLs 132g, 132r, and 132b of the first, second and third sub-pixel regions G, R, and B are disconnected from each other within the trench T, it may be difficult for charges to migrate through the first, second, and third EMLs 132g, 132r, and 132b between adjacent sub-pixel regions (G, R, and B).

The organic electroluminescent compound layer 130 according to the second embodiment of the present disclosure may minimize the problem of adjacent first, second, and third sub-pixel regions G, R, and B being affected by leakage current through the first, second, and third EMLs 132g, 132r, and 132b.

The first cavity length d1 between the first reflective electrode 117 positioned in the first sub-pixel regions G and the second electrode 140 may be formed shorter than the second cavity length d2 between the second reflective electrode 118 positioned in the second sub-pixel regions R and the second electrode 140, and longer than the third cavity length d3 between the third reflective electrode 119 positioned in the third sub-pixel regions B and the second electrode 140.

In particular, the wavelengths of red, green, and blue light may be in the order of red light>green light>blue light. Accordingly, the cavity lengths for red, green and blue light may also be in the order of red light>green light>blue light. That is, the transmittance peak corresponding to red light may appear at a longer wavelength band compared to green light and blue light.

Accordingly, the first cavity length d1 between the first reflective electrode 117 positioned in the first sub-pixel regions G and the second electrode 140 may be formed shorter than the second cavity length d2 between the second reflective electrode 118 positioned in the second sub-pixel regions R and the second electrode 140, and longer than the third cavity length d3 between the third reflective electrode 119 positioned in the third sub-pixel regions B and the second electrode 140.

The capping layer 160 and the encapsulation film 170 may be formed on the upper portion of the second electrode 140. The capping layer 160 and the encapsulation film 170 may be protective layers to protect the plurality of first, second and third organic electroluminescent compound layers 130g, 130r, and 130b and the second electrode 140 from moisture (H₂O ) and the like penetrating from the outside.

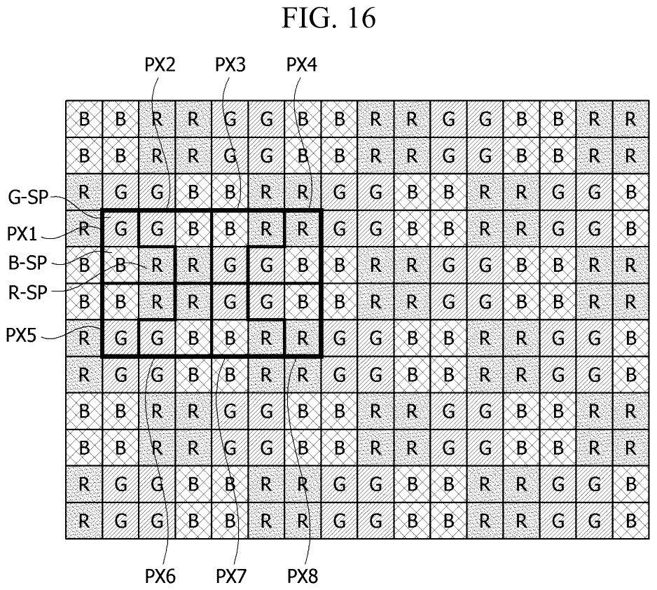

FIG. 16 is a plan view illustrating pixels composed of red, green, and blue sub-pixel regions of a display device according to a third embodiment of the present disclosure.

Referring to FIG. 16, in the display device according to the third embodiment of the present disclosure, first to eighth pixels PX1 to PX8 may be implemented by combining green, red, and blue sub-pixel regions G-SP, R-SP, and B-SP. In this case, the green, red, and blue sub-pixel regions G-SP, R-SP, and B-SP may also be described as green, red, and blue sub-pixel regions G, R, and B for convenience.

Here, the green, red, and blue sub-pixel regions G-SP, R-SP, and B-SP constituting each pixel PX may have the same area. However, the embodiments of the present disclosure are not limited thereto.

In addition, the first to eighth pixels PX1, PX2, PX3, PX4, PX5, PX6, PX7, and PX8 form one group and may be repeatedly disposed on the entire surface of the substrate in row and column directions. Here, each of the first to eighth pixels PX1, PX2, PX3, PX4, PX5, PX6, PX7, and PX8 may include one green sub-pixel region G, one red sub-pixel region R, and one blue sub-pixel regions B.

Specifically, among the first to eighth pixels PX1, PX2, PX3, PX4, PX5, PX6, PX7, and PX8 forming one group, the first and seventh pixels PX1 and PX7 may include pixels that combine a green sub-pixel region G in one row with blue and red sub-pixel regions B and R in another row adjacent to that row. For example, a blue sub-pixel region B may be disposed below the green sub-pixel region G constituting the first pixel PX1, and a red sub-pixel region R may be disposed next to the blue sub-pixel region B.

In addition, the second and eighth pixels PX2 and PX8 may include pixels that combine green and blue sub-pixel regions G and B in one row with a red sub-pixel region R in another row. For example, a blue sub-pixel region B may be disposed next to the green sub-pixel region G constituting the second pixel PX2, and a red sub-pixel region R may be disposed below the blue sub-pixel region B.

Further, the third and fifth pixels PX3 and PX5 may include pixels that combine blue and red sub-pixel regions B and R in one row with a green sub-pixel region G in another row. For example, a blue sub-pixel region B may be disposed next to the red sub-pixel region R constituting the third pixel PX3, and a green sub-pixel region G may be disposed below the blue sub-pixel region B.

In addition, the fourth and sixth pixels PX4 and PX6 may include pixels that combine a red sub-pixel region R in one row with green and blue sub-pixel regions G and B in another row. For example, a blue sub-pixel region B may be disposed below the red sub-pixel region R constituting the fourth pixel PX4, and a green sub-pixel region G may be disposed next to the blue sub-pixel region B.

Here, the first to fourth pixels PX1 to PX4 and the fifth to eighth pixels PX5 to PX8, which form one group, may be disposed in the same row direction. Additionally, the first to fourth pixels PX1 to PX4 and the fifth to eighth pixels PX5 to PX8 may be disposed in different row directions.

In addition, the blue and red sub-pixel regions B and R of the first pixel PX1 may be disposed to face and be in contact with the blue and red sub-pixel regions B and R of the fifth pixel PX5. For example, the blue sub-pixel region B of the first pixel PX1 may be disposed to face the blue sub-pixel region B of the fifth pixel PX5. In addition, the green sub-pixel region G of the first pixel PX1 may be disposed to face and be in contact with the green sub-pixel region G of the second pixel PX2.

Further, the blue sub-pixel region B and red sub-pixel region R of the second pixel PX2 may be disposed to face and be in contact with the blue sub-pixel region B and green sub-pixel region G of the third pixel PX3. For example, the blue sub-pixel region B of the second pixel PX2 may be disposed to face the blue sub-pixel region B of the third pixel PX3.

In addition, the green sub-pixel region G and blue sub-pixel region B of the fourth pixel PX4 may be disposed to face and be in contact with the green sub-pixel region G and blue sub-pixel region B of the eighth pixel PX8. For example, the blue sub-pixel region B of the fourth pixel PX4 may be disposed to face the blue sub-pixel region B of the eighth pixel PX8.

Further, the red and blue sub-pixel regions R and B of the sixth pixel PX6 may be disposed to face and be in contact with the green sub-pixel region G and blue sub-pixel region B of the seventh pixel PX7. For example, the red sub-pixel region R of the sixth pixel PX6 may be disposed to face the green sub-pixel region G of the seventh pixel PX7.

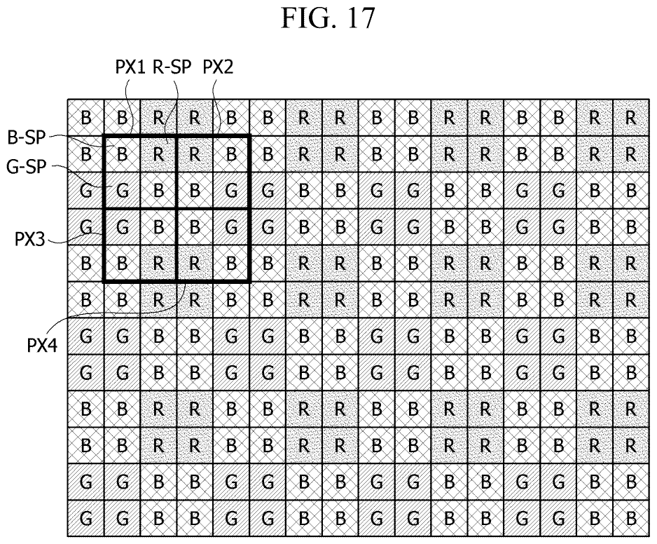

FIG. 17 is a plan view illustrating a case where pixels are composed of red, green, and blue sub-pixel regions of a display device according to a fourth embodiment of the present disclosure.

Referring to FIG. 17, in the display device according to the fourth embodiment of the present disclosure, the first to fourth pixels PX1 to PX4 may be implemented by combining the green, red, and blue sub-pixel regions G-SP, R-SP, and B-SP. In this case, the green, red, and blue sub-pixel regions G-SP, R-SP, and B-SP may be described as green, red, and blue sub-pixel regions G, R, and B for convenience.

Here, the green, red, and blue sub-pixel regions G-SP, R-SP, and B-SP constituting each pixel PX may have the same area. However, embodiments of the present disclosure are not limited thereto.

In addition, the first to fourth pixels PX1 to PX4 form one group and may be repeatedly disposed on the entire surface of the first substrate 111 in row and column directions. However, embodiments of the present disclosure are not limited thereto.

Here, each of the first and fourth pixels PX1 to PX4 may include two blue sub-pixel regions B, one red sub-pixel region R, and one green sub-pixel region G.

Further, the two blue sub-pixel regions B may be disposed to face each other in a diagonal direction. In addition, the red sub-pixel region R and the green sub-pixel region G may be disposed to face each other in a diagonal direction.

In addition, the red sub-pixel region R and blue sub-pixel region B of the first pixel PX1 may be disposed to face and be in contact with the red sub-pixel region R and blue sub-pixel region B of the second pixel PX2. In addition, the green sub-pixel region G and blue sub-pixel region B of the first pixel PX1 may be disposed to face and be in contact with the green sub-pixel region G and blue sub-pixel region B of the third pixel PX3.

Further, the blue sub-pixel region B and green sub-pixel region G of the second pixel PX2 may be disposed to face and be in contact with the blue sub-pixel region B and green sub-pixel region G of the fourth pixel PX4.

In addition, the blue sub-pixel region B and red sub-pixel region R of the third pixel PX3 may be disposed to face and be in contact with the blue sub-pixel region B and red sub-pixel region R of the fourth pixel PX4.

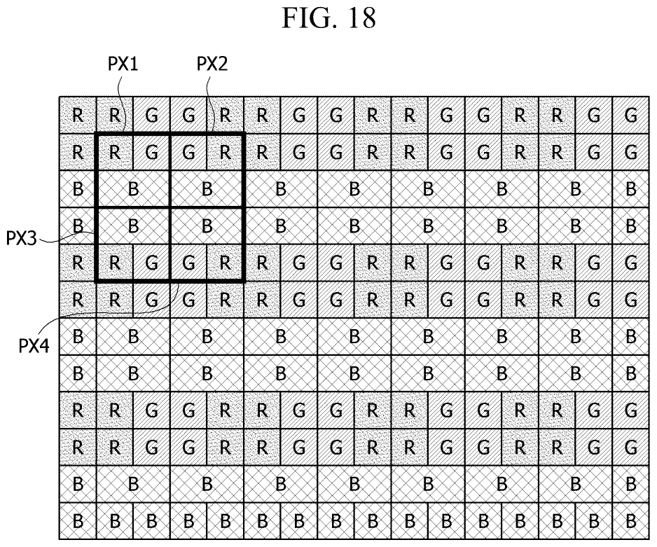

FIG. 18 is a plan view illustrating a case where pixels are composed of red, green, and blue sub-pixel regions of a display device according to a fifth embodiment of the present disclosure.

Referring to FIG. 18, in the display device according to the fifth embodiment of the present disclosure, first to fourth pixels PX1 to PX4 may be implemented by combining green, red, and blue sub-pixel regions G-SP, R-SP, and B-SP. In this case, the green, red, and blue sub-pixel regions G-SP, R-SP, and B-SP may be described as green, red, and blue sub-pixel regions G, R, and B for convenience.

Here, the green and red sub-pixel regions G-SP and R-SP and the blue sub-pixel region B-SP constituting each pixel PX may have different areas. Specifically, the blue sub-pixel region B-SP may have a larger area than the green and red sub-pixel regions G-SP and R-SP. For example, the blue sub-pixel region B may have an area at least twice as large as the red sub-pixel region R and the green sub-pixel region G. However, embodiments of the present disclosure are not limited thereto.

This is because the brightness of the blue sub-pixel region B is lower than that of the red sub-pixel region R and the green sub-pixel region G of the pixel PX and thus, the area of the blue sub-pixel region B may be formed larger than the red and green sub-pixel regions R and G to compensate for the brightness.

In addition, the first to fourth pixels PX1 to PX4 form one group and may be repeatedly disposed on the entire surface of the substrate in row and column directions. However, embodiments of the present disclosure are not limited thereto.

Here, each of the first to fourth pixels PX1 to PX4 may include one blue sub-pixel region B, one red sub-pixel region R, and one green sub-pixel region G.

Further, the blue sub-pixel region B of the first pixel PX1 may be disposed to be in contact with the blue sub-pixel regions B of the second to fourth pixels PX2, PX3, and PX4. Further, the red sub-pixel region R and green sub-pixel region G of each of the first to fourth pixels PX1 to PX4 may be disposed to face and be in contact with one long side of the blue sub-pixel region B of each of the first to fourth pixels PX1 to PX4.

In addition, the other long side of the blue sub-pixel region B of the first pixel PX1 may be disposed to face and be in contact with the other long side of the blue sub-pixel region B of the third pixel PX3.

Further, the other long side of the blue sub-pixel region B of the second pixel PX2 may be disposed to face and be in contact with the other long side of the blue sub-pixel region B of the fourth pixel PX4.

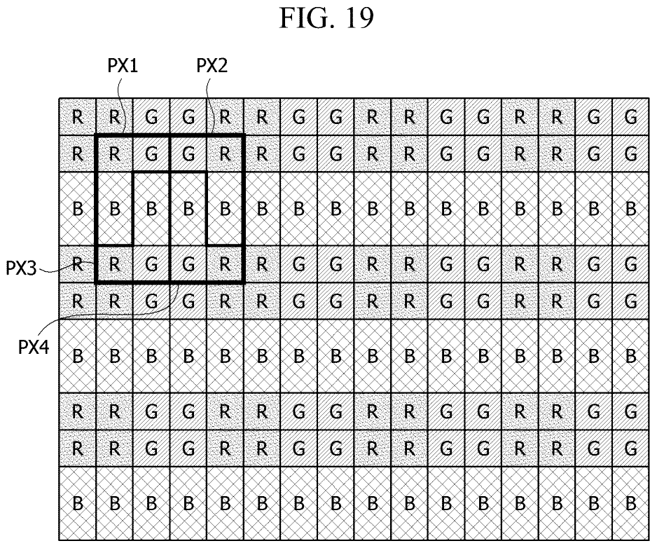

FIG. 19 is a plan view illustrating a case where pixels are composed of red, green, and blue sub-pixel regions of a display device according to a sixth embodiment of the present disclosure.

Referring to FIG. 19, in the display device according to the sixth embodiment of the present disclosure, first to fourth pixels PX1 to PX4 may be implemented by combining green, red, and blue sub-pixel regions G-SP, R-SP, and B-SP. In this case, the green, red, and blue sub-pixel regions G-SP, R-SP, and B-SP may be described as green, red, and blue sub-pixel regions G, R, and B for convenience.

Here, the green and red sub-pixel regions G-SP and R-SP and the blue sub-pixel region B-SP constituting each pixel PX may have different areas. Specifically, the blue sub-pixel region B-SP may have a larger area than those of the green and red sub-pixel regions G-SP and R-SP. For example, the blue sub-pixel region B may have an area at least twice as large as the red sub-pixel region R and the green sub-pixel region G. However, embodiments of the present disclosure are not limited thereto.

This is because the brightness of the blue sub-pixel region B is lower than those of the red sub-pixel region R and the green sub-pixel region G of the pixel PX and thus, the area of the blue sub-pixel region B may be formed larger than those of the red and green sub-pixel regions R and G to compensate for the brightness.

In addition, the first to fourth pixels PX1 to PX4 form one group and may be repeatedly disposed on the entire surface of the substrate in row and column directions. However, embodiments of the present disclosure are not limited thereto.

Here, each of the first and fourth pixels PX1 to PX4 may include one blue sub-pixel region B, one red sub-pixel region R, and one green sub-pixel region G.

Further, one long side of the blue sub-pixel region B of the first pixel PX1 may be disposed to face and be in contact with one long side of the blue sub-pixel region B of the third pixel PX3. In addition, the other long side of the blue sub-pixel region B of the third pixel PX3 may be disposed to face and be in contact with one long side of the blue sub-pixel region B of the fourth pixel PX4. Further, the other long side of the blue sub-pixel region B of the fourth pixel PX4 may be disposed to face and be in contact with one long side of the blue sub-pixel region B of the second pixel PX2.

In this case, the blue sub-pixel regions B of the first to fourth pixels PX1 to PX4 may be disposed in the same row direction.

In addition, one short side of the blue sub-pixel region B of the first pixel PX1 may be disposed to face and be in contact with the red sub-pixel region R of the third pixel PX3. Further, the green sub-pixel region G of the first pixel PX1 may be disposed to face and be in contact with the green sub-pixel region G of the second pixel PX2.

Further, one short side of the blue sub-pixel region B of the second pixel PX2 may be disposed to face and be in contact with the red sub-pixel region R of the fourth pixel PX4.

In addition, the green sub-pixel region G of the third pixel PX3 may be disposed to face and be in contact with the green sub-pixel region G of the fourth pixel PX4.

As described above, in the display device according to the embodiments of the present disclosure, each of the first to third sub-pixels SP1 to SP3 constituting the pixels PX may be partitioned into red, green, and blue sub-pixel regions, each of which is respectively partitioned into four areas on the first electrode, which is a separate anode electrode for each sub-pixel region. Here, the first electrode may be disposed to correspond to the red, green, and blue sub-pixel regions R, G, and B, each of which is partitioned into four areas.

In addition, according to one or more aspects of the present disclosure, the EML 132 corresponding to each of the four sub-pixel regions may be disposed by using a plurality of fine metal masks (FMMs) for the red, green, and blue sub-pixel regions R, G, and B, each of which is partitioned into four areas.

Accordingly, the degree of freedom in manufacturing the fine metal mask (FMM) may be improved by at least approximately four times, as the first electrode and the EML disposed in each of the red, green, and blue sub-pixel regions are partitioned into four areas.

Consequently, the opening area of the masks for forming the EML may be increased by at least four times, thereby lowering the difficulty of the mask manufacturing process and reducing mask clogging issues in proportion to the widened opening area, which in turn ensures mass-production efficiency.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a first sub-pixel, a second sub-pixel, and a third sub-pixel having different colors, each being partitioned into at least two sub-pixel regions by a trench;
a pixel including at least one of first sub-pixel regions partitioned in the first sub-pixel, at least one of second sub-pixel regions partitioned in the second sub-pixel, and at least one of third sub-pixel regions partitioned in the third sub-pixel;
a plurality of thin film transistors, wherein each thin film transistor is disposed to correspond to a respective one of a first sub-pixel region, a second sub-pixel region, and a third sub-pixel region;
an insulating layer provided on the plurality of thin film transistors;
a plurality of first electrodes disposed on the insulating layer, wherein each first electrode corresponds to a respective one of the first, second, and third sub-pixel regions, and each first electrode is connected to a corresponding one of the plurality of thin film transistors;
an organic electroluminescent compound layer disposed on the plurality of first electrodes; and
a second electrode disposed on an upper portion of the organic electroluminescent compound layer,
wherein the trench is provided within the insulating layer.

2. The display device according to claim 1, wherein:
a reflective electrode is disposed below each of the plurality of first electrodes; and
a first cavity length (d1) between the reflective electrode of the first sub-pixel region and the second electrode is shorter than a second cavity length (d2) between the reflective electrode of the second sub-pixel region and the second electrode, and longer than a third cavity length (d3) between the reflective electrode of the third sub-pixel region and the second electrode.

3. The display device according to claim 1, wherein the organic electroluminescent compound layer includes:
a hole layer disposed on each of the plurality of first electrodes;
an emission material layer disposed on the hole layer; and
an electron layer disposed on the emission material layer, and
wherein a first thickness of the electron layer positioned in the first sub-pixel region is thinner than a second thickness of the electron layer positioned in the second sub-pixel region, and thicker than a third thickness of the electron layer positioned in the third sub-pixel region.

4. The display device according to claim 1, wherein a thickness of a portion of the insulating layer in the first sub-pixel region is thicker than a thickness of a portion of the insulating layer in the second sub-pixel region, and thinner than a thickness of a portion of the insulating layer in the third sub-pixel region.

5. The display device according to claim 1, wherein:
the pixel is disposed in plurality; and
each of the plurality of pixels includes one of the first sub-pixel regions, one of the second sub-pixel regions, and one of the third sub-pixel regions having different colors, or includes one of the first sub-pixel regions, one of the second sub-pixel regions, and two of the third sub-pixel regions having different colors.

6. The display device according to claim 5, wherein:
the first sub-pixel region includes a green sub-pixel region;
the second sub-pixel region includes a red sub-pixel region; and
the third sub-pixel region includes a blue sub-pixel region.

7. The display device according to claim 6, wherein areas of the first sub-pixel region, the second sub-pixel region, and the third sub-pixel region are equal to each other, or an area of the third sub-pixel region is larger than areas of the first sub-pixel region and the second sub-pixel region.

8. The display device according to claim 1, wherein:
the pixel is provided in plurality;
the plurality of pixels form a group of at least four pixels, six pixels, or eight or more pixels,
the group is repeatedly disposed covering an entire surface of the substrate; and
each of the at least four pixels includes one of the first sub-pixel regions of green, one of the second sub-pixel regions of red, and two of the third sub-pixel regions of blue; or each of the at least six pixels includes one of the first sub-pixel regions of green, one of the second sub-pixel regions of red, and one of the third sub-pixel regions of blue; or each of the at least eight pixels includes one of the first sub-pixel regions of green, one of the second sub-pixel regions of red, and one of the third sub-pixel regions of blue.

9. The display device according to claim 8, wherein:
among the sub-pixel regions constituting the at least four pixels, areas of the first sub-pixel region of green, the second sub-pixel region of red, and the third sub-pixel region of blue are equal to each other, or an area of the third sub-pixel region of blue is larger than areas of the first sub-pixel region of green and the second sub-pixel region of red;
among the sub-pixel regions constituting the at least six pixels, an area of the third sub-pixel region of blue is larger than areas of the first sub-pixel region of green and the second sub-pixel region of red; and
among the sub-pixel regions constituting the at least eight pixels, areas of the first sub-pixel of green, the second sub-pixel region of red, and the third sub-pixel region of blue are equal to each other.

10. The display device according to claim 3, wherein the trench is formed with a width so that the hole layers and the emission material layers in adjacent sub-pixel regions are not in contact with each other at an upper portion of the trench, respectively.

11. The display device according to claim 10, wherein the trench is formed with the width so that the electron layers in adjacent sub-pixel regions are connected over the trench.

12. The display device according to claim 2, wherein first and second auxiliary insulating layers are disposed on the reflective electrodes in the first and second sub-pixel regions, respectively, and
wherein at least some of the plurality of first electrodes are disposed on the first and second auxiliary insulating layers in the first and second sub-pixel regions, respectively, and a thickness of the second auxiliary insulating layer is greater than a thickness of the first auxiliary insulating layer.

13. A display device, comprising:
a substrate;
a first sub-pixel, a second sub-pixel, and a third sub-pixel having different colors, each being partitioned into at least four sub-pixel regions by a trench; and
a pixel including at least one of first sub-pixel regions partitioned in the first sub-pixel, at least one of second sub-pixel regions partitioned in the second sub-pixel, and at least one of third sub-pixel regions partitioned in the third sub-pixel,
wherein a plurality of pixels form a group and are repeatedly disposed covering the substrate.

14. The display device according to claim 13, wherein each of the plurality of pixels includes one of the first sub-pixel regions, one of the second sub-pixel regions, and one of the third sub-pixel regions, or includes one of the first sub-pixel regions, one of the second sub-pixel regions, and two of the third sub-pixel regions.

15. The display device according to claim 14, wherein a first sub-pixel region includes a green sub-pixel region, a second sub-pixel region includes a red sub-pixel region, and a third sub-pixel region includes a blue sub-pixel region, and
wherein the first sub-pixel region comprises the at least one of the first sub-pixel regions, the second sub-pixel region comprises the at least one of the second sub-pixel regions, and the third sub-pixel region comprises the at least one of the third sub-pixel regions.

16. The display device according to claim 15, wherein areas of the first sub-pixel region, the second sub-pixel region, and the third sub-pixel region are equal to each other, or an area of the third sub-pixel region is larger than areas of the first sub-pixel region and the second sub-pixel region.

17. The display device according to claim 15, wherein:
the group is composed of four, six, or eight or more pixels and is repeatedly disposed covering an entire surface of the substrate;
each of the plurality of pixels disposed in the group composed of four pixels includes one of the first sub-pixel regions, one of the second sub-pixel regions, and two of the third sub-pixel regions;
each of the plurality of pixels disposed in the group composed of six pixels includes one of the first sub-pixel regions, one of the second sub-pixel regions, and one of the third sub-pixel regions; or
each of the plurality of pixels disposed in the group composed of eight pixels includes one of the first sub-pixel regions, one of the second sub-pixel regions, and one of the third sub-pixel regions.

18. The display device according to claim 17, wherein:
among the sub-pixel regions constituting the pixel disposed in the group composed of the four pixels, areas of the first sub-pixel region, the second sub-pixel region, and the third sub-pixel region are equal to each other, or an area of the third sub-pixel region is larger than areas of the first sub-pixel region and the second sub-pixel region;
among the sub-pixel regions constituting the pixel disposed in the group composed of the six pixels, an area of the third sub-pixel region is larger than areas of the first sub-pixel region and the second sub-pixel region; and
among the sub-pixel regions constituting the pixel disposed in the group composed of the eight pixels, areas of the first sub-pixel region, the second sub-pixel region, and the third sub-pixel region are equal to each other.
